(19) United States
(12) Patent Application Publication
(10) Pub. No.: US 2020/0321541 A1
(43) Pub. Date: Oct. 8, 2020

(54) LIGHT EMITTING ELEMENT, LIGHT-EMITTING DEVICE, DISPLAY DEVICE, ELECTRONIC DEVICE, AND LIGHTING DEVICE

(71) Applicant: Semiconductor Energy Laboratory Co., Ltd., Atsugi-shi (JP)

(72) Inventors: Shunsuke HOSOUMI, Atsugi (JP); Tatsuyoshi TAKAHASHI, Atsugi (JP); Takahiro ISHISONE, Atsugi (JP); Satoshi SEO, Sagamihara (JP)

(21) Appl. No.: 16/851,344

(22) Filed: Apr. 17, 2020

Related U.S. Application Data
(63) Continuation of application No. 15/164,599, filed on May 25, 2016, now abandoned.

(30) Foreign Application Priority Data
May 29, 2015 (JP) 2015-109818

(51) Int. Cl. H01L 51/00; H01L 51/50

(52) U.S. Cl. CPC H01L 51/0074; H01L 51/5012; H01L 51/5028; H01L 51/006; Y02P 20/582; H01L 51/0071; H01L 51/0061; H01L 51/0054; H01L 51/0072

(57) ABSTRACT

A light-emitting element which exhibits high emission efficiency is provided without using a rare metal as a light-emitting material. The light-emitting element including a first electrode, a second electrode, and a layer containing organic compounds between the first electrode and the second electrode is provided. The layer containing organic compounds includes a light-emitting layer at least containing a fluorescent substance. The light-emitting layer includes a fluorescent substance, a first organic compound, and a second organic compound. The combination of the first organic compound and the second organic compound forms an exciplex. The first organic compound is a substance having the first skeleton including a benzofuropyrimidine skeleton or a benzothienopyrimidine skeleton.

### CROSS-REFERENCE TO RELATED APPLICATIONS

This application is a continuation of U.S. application Ser. No. 15/164,599, filed May 25, 2016, now pending, which claims the benefit of a foreign priority application filed in Japan as Serial No. 2015-109818 on May 29, 2015, both of which are incorporated by reference.

### BACKGROUND OF THE INVENTION

### 1. Field of the Invention

The present invention relates to a light-emitting element, a display device, a light-emitting device, an electronic appliance, and a lighting device each of which uses an organic compound as a light-emitting substance.

### 2. Description of the Related Art

Advances are being made in application of a current excitation type light-emitting element in which an organic compound is used as a light-emitting substance, i.e., an organic EL element, to light sources, lighting, displays, and the like.

As is known, in an organic EL element, the generation ratio of excitons in a singlet excited state to excitons in a triplet excited state is 1:3. Thus, the limit value of internal quantum efficiency of fluorescence, which is emitted by conversion of a singlet excited state into light emission, is 25%, while phosphorescence, which is emitted by conversion of a triplet excited state into light emission, can have an internal quantum efficiency of 100% when energy transfer via intersystem crossing from a singlet excited state is taken into account. In view of the above, an organic EL element (also referred to as a phosphorescent light-emitting element) in which a phosphorescent material is used as a light-emitting substance is selected in many cases so that light is emitted efficiently.

Most of substances capable of efficiently converting triplet excitation state into light emission are organometallic complexes, and in most cases, central metals of the organometallic complexes are rare metals whose production is small. The price of rare metals is high and greatly fluctuates, and supply thereof might be unstable depending on the global situation. For this reason, there are some concerns about cost and supply regarding phosphorescent light-emitting elements.

In contrast, although fluorescent substances do not have efficiency as high as that of phosphorescent substances, most of them do not have a problem in supply or price. Furthermore, many fluorescent substances that have stability of lifetime or the like and emit light of a favorable color have been found.

To cause conversion of a triplet excited state into light emission, delayed fluorescence can also be utilized. In this case, not phosphorescence but fluorescence is obtained because reverse intersystem crossing from a triplet excited state to a singlet excited state is utilized and the light emission occurs from a singlet excited state. This is readily caused when an energy difference between a singlet excited state and a triplet excited state is small. Emission efficiency exceeding the theoretical limit of emission efficiency of fluorescence has been actually reported.

It has been reported that a fluorescent light-emitting element with high emission efficiency is obtained by transferring energy from a substance exhibiting thermally activated delayed fluorescence (hereinafter, also referred to as TADF) to a fluorescent substance.

It has also been reported that an exciplex (excited complex) formed of two kinds of substances was utilized to achieve a state where an energy difference between a singlet excited state and a triplet excited state is small and TADF is obtained, whereby a high-efficiency light-emitting element was provided.

### REFERENCE

### Non-Patent Document

### [Non-Patent Document 1] K. Goushi et al., Applied Physics Letters, 101, pp. 023306/1-023306/4 (2012).

### SUMMARY OF THE INVENTION

In the case of a TADF material which obtains TADF from a single molecule, a special structure where a singlet excitation energy level and a triplet excitation energy level are close to each other needs to be achieved; thus, there is a serious limitation on its molecular design.

The excited level of a substance to be an energy donor needs to be in an appropriate position to efficiently excite a fluorescent substance. However, it is difficult to optimize the excited level in the case where the TADF material with the limited molecular design is used for the energy donor of the fluorescent substance.

In contrast, in the case where TADF is obtained from an exciplex, since it is known that its energy gap corresponds to a difference between the higher HOMO level and the lower LUMO level of two substances that form the exciplex, an exciplex with an appropriate singlet excitation energy level is easily obtained according to the combination of the substances used. Since a singlet excitation energy level and a triplet excitation energy level are adjacent to each other in an exciplex, the position of the triplet excitation energy level can be easily set.

However, even in the case of the fluorescent light-emitting element whose excited levels are optimized by using the exciplex as an energy donor, efficiency greatly varies depending on substances that form an exciplex. There is no guideline for selecting substances to obtain a fluorescent light-emitting element with favorable efficiency.

In view of the above, an object of one embodiment of the present invention is to provide a light-emitting element which has high emission efficiency. Another object of one embodiment of the present invention is to provide a light-emitting element which has high emission efficiency without using a rare metal as a light-emitting material. Another object of one embodiment of the present invention is to provide a fluorescent light-emitting element which utilizes energy transfer from an exciplex and has high efficiency.

A yet still further object of one embodiment of the present invention is to provide a light-emitting device, a display device, an electronic device, and a lighting device each of which has high emission efficiency by using any of the above light-emitting elements.

It is only necessary that at least one of the above-described objects be achieved in the present invention.

One embodiment of the present invention is a light-emitting element that includes a first electrode, a second electrode, and a layer containing organic compounds between the first electrode and the second electrode. The layer containing organic compounds includes a light-emitting layer containing at least a fluorescent substance. The light-emitting layer includes the fluorescent substance, a first organic compound, and a second organic compound. A combination of the first organic compound and the second organic compound forms an exciplex. The first organic compound is a substance having a first skeleton including a benzofuropyrimidine skeleton or a benzothienopyrimidine skeleton.

Another embodiment of the present invention is the light-emitting element having above structure in which the first skeleton includes a benzofuro[3,2-d]pyrimidine skeleton or a benzothieno[3,2-d]pyrimidine skeleton.

Another embodiment of the present invention is the light-emitting element having the above structure in which the first skeleton is a benzofuropyrimidine skeleton.

Another embodiment of the present invention is the light-emitting element having the above structure in which the first skeleton is a benzofuro[3,2-d]pyrimidine skeleton.

Another embodiment of the present invention is the light-emitting element having the above structure in which the benzofuro[3,2-d]pyrimidine skeleton or the benzothieno[3,2-d]pyrimidine skeleton has a substituent at the 4-position.

Another embodiment of the present invention is the light-emitting element having the above structure in which the benzofuro[3,2-d]pyrimidine skeleton or the benzothieno[3,2-d]pyrimidine skeleton has a substituent only at the 4-position.

Another embodiment of the present invention is the light-emitting element having the above structure in which the first organic compound further includes a second skeleton including a carbazole skeleton or a dibenzothiophene skeleton.

Another embodiment of the present invention is the light-emitting element having the above structure in which the second skeleton is a carbazole skeleton, and the 9-position of the carbazole skeleton is substituted.

Another embodiment of the present invention is the light-emitting element having the above structure in which the second skeleton is a dibenzothiophene skeleton, and the 4-position of the dibenzothiophene skeleton is substituted.

Another embodiment of the present invention is the light-emitting element having the above structure in which the first organic compound is a substance in which the first skeleton and the second skeleton are connected via a bivalent linking group.

Another embodiment of the present invention is the light-emitting element having the above structure in which the first skeleton is a benzofuro[3,2-d]pyrimidine skeleton or a benzothieno[3,2-d]pyrimidine skeleton and the 4-position of the first skeleton is bonded to the linking group.

Another embodiment of the present invention is the light-emitting element having the above structure in which the second skeleton is a dibenzothiophene skeleton and the 4-position of the dibenzothiophene skeleton is bonded to the linking group.

Another embodiment of the present invention is the light-emitting element having the above structure, in which the second skeleton is a carbazole skeleton and the 9-position of the carbazole skeleton is bonded to the linking group.

Another embodiment of the present invention is the light-emitting element having the above structure in which the linking group is a bivalent group having 6 to 60 carbon atoms.

Another embodiment of the present invention is the light-emitting element having the above structure in which the linking group is a bivalent aromatic hydrocarbon group having 6 to 60 carbon atoms.

Another embodiment of the present invention is the light-emitting element having the above structure in which the linking group is a substituted or unsubstituted bivalent group having 6 to 13 carbon atoms.

Another embodiment of the present invention is the light-emitting element having the above structure in which the linking group is a substituted or unsubstituted bivalent aromatic hydrocarbon group having 6 to 13 carbon atoms.

Another embodiment of the present invention is the light-emitting element having the above structure in which the linking group is a biphenyldiyl group.

Another embodiment of the present invention is the light-emitting element having the above structure in which the biphenyldiyl group is a 3,3′-biphenyldiyl group.

Another embodiment of the present invention is the light-emitting element having the above structure, in which a triplet excitation energy level of the exciplex is higher than a triplet excitation energy level of the fluorescent substance.

Another embodiment of the present invention is the light-emitting element having the above structure in which a triplet excitation energy level of each of the first organic compound and the second organic compound is higher than the triplet excitation energy level of the exciplex.

Another embodiment of the present invention is the light-emitting element having the above structure in which light-emission of the exciplex overlaps with the lowest-energy-side absorption band of the fluorescent substance.

Another embodiment of the present invention is the light-emitting element having the above structure in which the first organic compound is a substance in which an electron-transport property is higher than a hole-transport property, and the second organic compound is a substance in which a hole-transport property is higher than an electron-transport property.

Another embodiment of the present invention is the light-emitting element having the above structure in which the second organic compound includes a π-electron rich heteroaromatic ring skeleton or an aromatic amine skeleton.

Another embodiment of the present invention is the light-emitting element having the above structure in which a proportion of the delayed fluorescence in PL emission of the exciplex is greater than or equal to 5%, preferably greater than or equal to 10%, and further preferably greater than or equal to 20%.

Another embodiment of the present invention is the light-emitting element having the above structure in which a lifetime of the delayed fluorescence in PL emission of the exciplex is greater than or equal to 1 μs and less than or equal to 50 μs, preferably greater than or equal to 1 μs and less than or equal to 40 μs, further preferably greater than or equal to 1 μs and less than or equal to 30 μs.

Another embodiment of the present invention is a light-emitting device including the light-emitting element with any of the above structures and a transistor or a substrate.

Another embodiment of the present invention is an electronic device including the light-emitting device having the above structure, a sensor, an operation button, a speaker, or a microphone.

Another embodiment of the present invention is a lighting device which includes the light-emitting element having any of the above structures and a housing.

Note that the light-emitting device in this specification includes an image display device using a light-emitting element. The light-emitting device may be included in a module in which a light-emitting element is provided with a connector such as an anisotropic conductive film or a tape carrier package (TCP), a module in which a printed wiring board is provided at the end of a TCP, and a module in which an integrated circuit (IC) is directly mounted on a light-emitting element by a chip on glass (COG) method. The light-emitting device may be included in lighting equipment.

In one embodiment of the present invention, a novel light-emitting element can be provided. In one embodiment of the present invention, a light-emitting element which has high emission efficiency can be provided. One embodiment of the present invention can provide a light-emitting element which has high emission efficiency without using a rare metal as a light-emitting material. In one embodiment of the present invention, a light-emitting element which utilizes an exciplex and has high efficiency can be provided. In one embodiment of the present invention, a light-emitting element which emits light from an exciplex and has high efficiency can be provided.

In one embodiment of the present invention, a light-emitting device, a display device, an electronic device, and a lighting device each having high emission efficiency can be provided.

It is only necessary that at least one of the above effects be achieved in one embodiment of the present invention. Note that the description of these effects does not disturb the existence of other effects. One embodiment of the present invention does not necessarily achieve all these effects. Other effects will be apparent from and can be derived from the description of the specification, the drawings, the claims, and the like.

### BRIEF DESCRIPTION OF THE DRAWINGS

FIGS. 1A to 1C illustrate light-emitting elements.

FIGS. 2A and 2B illustrate an active matrix light-emitting device.

FIGS. 3A and 3B illustrate an active matrix light-emitting device.

FIG. 4 illustrates an active matrix light-emitting device.

FIGS. 5A and 5B illustrate a passive matrix light-emitting device.

FIGS. 6A and 6B illustrate a lighting device.

FIGS. 7A, 7B1, 7B2, and 7C illustrate electronic devices.

FIG. 8 illustrates a light source device.

FIG. 9 illustrates a lighting device.

FIG. 10 illustrates a lighting device.

FIG. 11 illustrates in-vehicle display devices and lighting devices.

FIGS. 12A to 12C illustrate an electronic appliance.

FIGS. 13A to 13C illustrate an electronic device.

FIG. 14 shows luminance-current density characteristics of Light-emitting Elements 1 to 4.

FIG. 15 shows current efficiency-luminance characteristics of Light-emitting Elements 1 to 4.

FIG. 16 shows luminance-voltage characteristics of Light-emitting Elements 1 to 4.

FIG. 17 shows current-voltage characteristics of Light-emitting Elements 1 to 4.

FIG. 18 shows external quantum efficiency vs. luminance plots of the light-emitting Elements 1 to 4.

FIG. 19 shows the emission spectra of Light-emitting Elements 1 to 4.

FIG. 20 is an example illustrating the correlation of energy levels in a light-emitting element of one embodiment of the present invention.

FIGS. 21A to 21D each show emission spectra of a first organic compound, a second organic compound, and an exciplex formed of the first and second organic compounds.

### DETAILED DESCRIPTION OF THE INVENTION

Embodiments of the present invention will be explained below with reference to the drawings. Note that the present invention is not limited to the description below, and it is easily understood by those skilled in the art that various changes and modifications can be made without departing from the spirit and scope of the present invention. Accordingly, the present invention should not be construed as being limited to the description of the embodiments below.

### Embodiment 1

As a method for converting a triplet excited state into light emission, there are a method utilizing phosphorescence, which is direct emission from a triplet excited state, and a method utilizing delayed fluorescence, which is light emitted from a singlet excited state after a triplet excited state is turned into a singlet excited state via reverse intersystem crossing.

A structure of a light-emitting element that uses a phosphorescent material and emits light with extremely high efficiency has been reported, which proves advantages of the utilization of a triplet excited state for light emission. However, central metals of phosphorescent materials are mostly rare metals, and there are concerns about cost and supply in mass production.

Some degree of success in a light-emitting element using a delayed fluorescence material has been achieved in recent years. However, a substance emitting delayed fluorescence with relatively high efficiency has an extremely rare state where a singlet excited state and a triplet excited state are close to each other and accordingly has a unique molecular structure; thus, the kind of such a substance is still limited.

It has been reported that an exciplex (also called excited complex) is a complex in an excited state which is formed by two kinds of molecules due to charge-transfer interaction and that the singlet excited state and the triplet excited state of an exciplex are close to each other in many cases. Therefore, reverse intersystem crossing from the triplet excitation energy level of the exciplex to the singlet excitation energy level thereof is likely to occur even at room temperature. Thus, a fluorescent light-emitting element with a favorable efficiency can be obtained by using the exciplex for an energy donor of a fluorescent substance. The energy gap of an exciplex corresponds to an energy difference between a higher HOMO level and a lower LUMO level of the two kinds of substances that form the complex. For this reason, an exciplex having a singlet excitation energy level and a triplet excitation energy level, which are preferable for energy transfer to an excited fluorescent substance, can be obtained relatively easily by selection of substances forming the exciplex.

However, positive use of energy transfer from the exciplex to the fluorescent substance is still under investigation, and there are few guidelines for selecting substances to achieve high emission efficiency. Without any guideline, a favorable light-emitting element will never be provided.

In view of the above, a structure of a light-emitting element that emits light with high efficiency by using an exciplex as an energy donor of a fluorescent substance is disclosed in this embodiment.

A light-emitting element in this embodiment includes a layer containing organic compounds (the layer may also contain an inorganic compound) between a pair of electrodes, and the layer containing organic compounds at least includes a light-emitting layer (a layer having a function of emitting light). The light-emitting layer includes a first organic compound, a second organic compound, and a fluorescent substance.

A combination of the first organic compound and the second organic compound forms an exciplex. To form the exciplex, the HOMO level and LUMO level of the first organic compound are preferably lower than the HOMO level and LUMO level of the second organic compound, respectively.

The formation process of the exciplex is considered to be roughly classified into the following two processes.

One formation process is the process in which an exciplex is formed of the first organic compound having an electron-transport property and the second organic compound having a hole-transport property which have different carriers (cation or anion).

The other formation process is an elementary process in which one of the first organic compound and the second organic compound forms a singlet exciton and then interacts with the other in the ground state to form an exciplex.

The exciplex in one embodiment of the present invention may be formed by either process.

Although it is acceptable as long as the combination of the first organic compound and the second organic compound can form an exciplex, it is preferable that one of them be a compound having a function of transporting holes (a hole-transport property) and the other be a compound having a function of transporting electrons (an electron-transport property). In that case, an exciplex is easily formed; thus, the exciplex can be formed efficiently. In the case where the combination of the first organic compound and the second organic compound is a combination of a compound having an electron-transport property and a compound having a hole-transport property, the carrier balance can be easily controlled depending on the mixture ratio. Specifically, the weight ratio of the compound having a hole-transport property to the compound having an electron-transport property is preferably within a range of 1:9 to 9:1. Since the carrier balance can be easily controlled with the structure, a carrier recombination region can also be controlled easily.

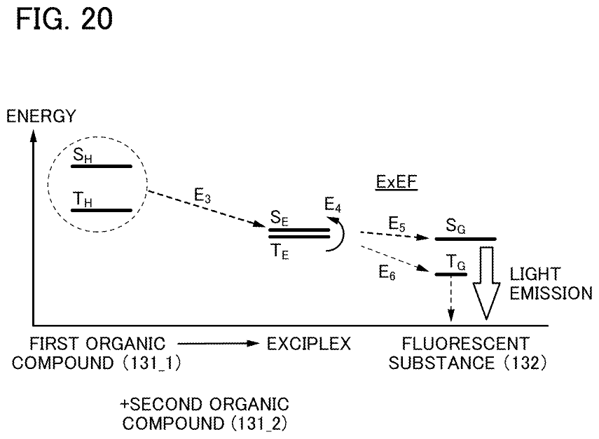

FIG. 20 shows an example of a correlation of energy levels of a first organic compound 131_1, a second organic compound 131_2, and a fluorescent substance 132 in the light-emitting layer.

In the light-emitting element of one embodiment of the present invention, the first organic compound 131_1 and the second organic compound 131_2 included in the light-emitting layer form an exciplex. In the exciplex, the lowest singlet excitation energy level (S_{E}) and the lowest triplet excitation energy level (T_{E}) are close to each other.

An exciplex is an excited state formed from two kinds of substances. In the case of photoexcitation, the exciplex is formed by interaction between one substance in an excited state and the other substance in a ground state. The two kinds of substances that have formed the exciplex return to a ground state by emitting light and serve as the original two kinds of substances. In the case of electrical excitation, when one substance is brought into an excited state, the one interacts with the other substance to form an exciplex. Alternatively, one substance receiving a hole and the other substance receiving an electron come close to each other to form an exciplex. In this case, an exciplex is formed immediately, and thus most excitons in the light-emitting layer can exist as exciplexes. Because the singlet excitation energy level (S_{E}) of the exciplex is lower than the singlet excitation energy level (S_{H}) of the host materials (the first organic compound 131_1 and the second organic compound 131_2) that form the exciplex, the excited state can be formed with lower excitation energy. Accordingly, the driving voltage of the light-emitting element can be reduced.

Since the singlet excitation energy level (S_{E}) and the triplet excitation energy level (T_{E}) of the exciplex are adjacent to each other, the exciplex may exhibit thermally activated delayed fluorescence. In other words, the exciplex has a function of converting triplet excitation energy to singlet excitation energy by reverse intersystem crossing (upconversion) (see Route E₄ in FIG. 20). Thus, the triplet excitation energy generated in the light-emitting layer is partly converted into singlet excitation energy by the exciplex. In order to cause this conversion, the energy difference between the singlet excitation energy level (S_{E}) and the triplet excitation energy level (T_{E}) of the exciplex is preferably greater than or equal to 0 eV and less than or equal to 0.2 eV. Note that in order to efficiently make reverse intersystem crossing occur, the triplet excitation energy levels of the organic compounds (the first organic compound 131_1 and the second organic compound 131_2) in the host materials which form the exciplex is preferably higher than the triplet excitation energy level (T_{E}) of the exciplex. Thus, quenching of the triplet excitation energy of the exciplex due to the organic compounds is less likely to occur, which causes reverse intersystem crossing efficiently.

Furthermore, the singlet excitation energy level of the exciplex (S_{E}) is preferably higher than the singlet excitation energy level of the fluorescent substance 132 (S_{G}). In this way, the singlet excitation energy of the formed exciplex can be transferred from the singlet excitation energy level of the exciplex (S_{E}) to the singlet excitation energy level of the fluorescent substance 132 (S_{G}), so that the fluorescent substance 132 is brought into the singlet excited state, causing light emission (see Route E₅ in FIG. 20).

To obtain efficient light emission from the singlet excited state of the fluorescent substance 132, the fluorescence quantum yield of the fluorescent substance 132 is preferably high, and specifically, 50% or higher, further preferably 70% or higher, still further preferably 90% or higher.

Note that since direct transition from a singlet ground state to a triplet excited state in the fluorescent substance 132 is forbidden, energy transfer from the singlet excitation energy level of the exciplex (S_{E}) to the triplet excitation energy level of the fluorescent substance 132 (T_{G}) is unlikely to be a main energy transfer process.

When transfer of the triplet excitation energy from the triplet excitation energy level of the exciplex (T_{E}) to the triplet excitation energy level of the fluorescent substance 132 (T_{G}) occurs, the triplet excitation energy is deactivated (see Route E₆ in FIG. 20). Thus, it is preferable that the energy transfer of Route E₆ be less likely to occur because the probability of generating the triplet excited state of the fluorescent substance 132 can be decreased and thermal deactivation can be reduced. To achieve this, it is preferable that the concentration of the fluorescent substance 132 with respect to the host material be low. Accordingly, since a light-emitting element with high efficiency can be obtained, the triplet excitation energy level (T_{E}) of the exciplex is higher than the triplet excitation energy level (T_{G}) of the fluorescent substance in one embodiment of the present invention.

When the direct carrier recombination process in the fluorescent substance 132 is dominant, a large number of triplet excitons are generated in the light-emitting layer, resulting in decreased emission efficiency due to thermal deactivation. Thus, it is preferable that the probability of the energy transfer process through the exciplex formation process (Routes E₄ and E₅ in FIG. 20) be higher than the probability of the direct carrier recombination process in the fluorescent substance 132 because the probability of generating the triplet excited state of the fluorescent substance 132 can be decreased and thermal deactivation can be reduced. Therefore, also in this case, it is preferable that the concentration of the fluorescent substance 132 with respect to the host material be low.

The concentration of the fluorescent substance 132 with respect to the host material is preferably greater than or equal to 0.1 wt % and less than or equal to 5 wt %, more preferably greater than or equal to 0.1 wt % and less than or equal to 1 wt %.

By making all the energy transfer processes of Routes E₄ and E₅ efficiently occur in the above-described manner, both the singlet excitation energy and the triplet excitation energy of the host material can be efficiently converted into the singlet excited state of the fluorescent substance 132, whereby the light-emitting element in this embodiment can emit light with high emission efficiency.

The above-described processes through Routes E₃, E₄, and E₅ may be referred to as exciplex-singlet energy transfer (ExSET) or exciplex-enhanced fluorescence (ExEF) in this specification and the like. In other words, in the light-emitting layer, excitation energy is given from the exciplex to the fluorescent substance 132.

When the light-emitting layer has the above-described structure, light emission from the fluorescent substance 132 of the light-emitting layer can be obtained efficiently.

Next, factors controlling the processes of intermolecular energy transfer between the host material and the fluorescent substance 132 will be described. As mechanisms of the intermolecular energy transfer, two mechanisms, i.e., Förster mechanism (dipole-dipole interaction) and Dexter mechanism (electron exchange interaction), have been proposed. Although the intermolecular energy transfer process between the host material and the fluorescent substance 132 is described here, the same can apply to a case where the host material is an exciplex.

### <<Förster Mechanism>>

In Förster mechanism, energy transfer does not require direct contact between molecules and energy is transferred through a resonant phenomenon of dipolar oscillation between the host material and the fluorescent substance 132. By the resonant phenomenon of dipolar oscillation, the host material provides energy to the fluorescent substance 132, and thus, the host material is brought into a ground state and the fluorescent substance 132 is brought into an excited state. Note that the rate constant k_{h*→g} of Förster mechanism is expressed by Formula (1).

$$\begin{matrix}[ Formula 1 ] & \\ {k}_{{h}^{*} \to g} = \frac{9000 {K}^{2} φln10}{128 {π}^{5} {n}^{4} N τ {R}^{6}} \int \frac{{f}_{h}^{′} ( v ) {ɛ}_{g} ( v )}{{v}^{4}} dv & ( 1 )\end{matrix}$$

In Formula (1), v denotes a frequency, f′ₕ(v) denotes a normalized emission spectrum of the host material (a fluorescent spectrum in energy transfer from a singlet excited state, and a phosphorescent spectrum in energy transfer from a triplet excited state), ϵ_{g}(v) denotes a molar absorption coefficient of the fluorescent substance 132, N denotes Avogadro's number, n denotes a refractive index of a medium, R denotes an intermolecular distance between the host material and the fluorescent substance 132, τ denotes a measured lifetime of an excited state (fluorescence lifetime or phosphorescence lifetime), c denotes the speed of light, ϕ denotes a luminescence quantum yield (a fluorescence quantum yield in energy transfer from a singlet excited state, and a phosphorescence quantum yield in energy transfer from a triplet excited state), and K² denotes a coefficient (0 to 4) of orientation of a transition dipole moment between the host material and the fluorescent substance 132. Note that K²=2/3 in random orientation.

### <<Dexter Mechanism>>

In Dexter mechanism, the host material and the fluorescent substance 132 are close to a contact effective range where their orbitals overlap, and the host material in an excited state and the fluorescent substance 132 in a ground state exchange their electrons, which leads to energy transfer. Note that the rate constant k_{h*→g} of Dexter mechanism is expressed by Formula (2).

$$\begin{matrix}[ Formula 2 ] & \\ {k}_{{h}^{*} \to g} = ( \frac{2 π}{h} ) {K}^{2} exp ( - \frac{2 R}{L} ) \int {f}_{h}^{′} ( v ) {ɛ}_{g}^{′} ( v ) dv & ( 2 )\end{matrix}$$

In Formula (2), h denotes a Planck constant, K denotes a constant having an energy dimension, v denotes a frequency, f′ₕ(v) denotes a normalized emission spectrum of the host material (a fluorescent spectrum in energy transfer from a singlet excited state, and a phosphorescent spectrum in energy transfer from a triplet excited state), ϵ′_{g}(v) denotes a normalized absorption spectrum of the fluorescent substance 132, L denotes an effective molecular radius, and R denotes an intermolecular distance between the host material and the fluorescent substance 132.

Here, the efficiency of energy transfer from the host material to the fluorescent substance 132 (energy transfer efficiency ϕ_{ET}) is thought to be expressed by Formula (3). In the formula, kᵣ denotes a rate constant of a light-emission process (fluorescence in energy transfer from a singlet excited state, and phosphorescence in energy transfer from a triplet excited state) of the host material, kₙ denotes a rate constant of a non-light-emission process (thermal deactivation or intersystem crossing) of the host material, and τ denotes a measured lifetime of an excited state of the host material.

$$\begin{matrix}[ Formula 3 ] & \\ {φ}_{ET} = \frac{{k}_{{h}^{*} \to g}}{{k}_{r} + {k}_{n} + {k}_{{h}^{*} \to g}} = \frac{{k}_{{h}^{*} \to g}}{( \frac{1}{τ} ) + {k}_{{h}^{*} \to g}} & ( 3 )\end{matrix}$$

According to Formula (3), it is found that the energy transfer efficiency ϕ_{ET} can be increased by increasing the rate constant k_{h*→g} of energy transfer so that another competing rate constant kᵣ+kₙ(=1/τ) becomes relatively small.

### <<Concept for Promoting Energy Transfer>>

First, an energy transfer by Förster mechanism is considered. When Formula (1) is substituted into Formula (3), τ can be eliminated. Thus, in Förster mechanism, the energy transfer efficiency ϕ_{ET} does not depend on the lifetime τ of the excited state of the host material. In addition, it can be said that the energy transfer efficiency ϕ_{ET} is higher when the luminescence quantum yield ϕ (here, the fluorescence quantum yield because energy transfer from a singlet excited state is discussed) is higher. In general, the luminescence quantum yield of an organic compound in a triplet excited state is extremely low at room temperature. Thus, in the case where the host material is in a triplet excited state, a process of energy transfer by Förster mechanism can be ignored, and a process of energy transfer by Förster mechanism is considered only in the case where the host material is in a singlet excited state.

Furthermore, it is preferable that the emission spectrum (the fluorescent spectrum in the case where energy transfer from a singlet excited state is discussed) of the host material largely overlap with the absorption spectrum (absorption corresponding to the transition from the singlet ground state to the singlet excited state) of the fluorescent substance 132. Moreover, it is preferable that the molar absorption coefficient of the fluorescent substance 132 be also high. This means that the emission spectrum of the host material overlaps with the absorption band of the fluorescent substance 132 which is on the longest wavelength side. Since direct transition from the singlet ground state to the triplet excited state of the fluorescent substance 132 is forbidden, the molar absorption coefficient of the fluorescent substance 132 in the triplet excited state can be ignored. Thus, a process of energy transfer to a triplet excited state of the fluorescent substance 132 by Förster mechanism can be ignored, and only a process of energy transfer to a singlet excited state of the fluorescent substance 132 is considered. That is, in Förster mechanism, a process of energy transfer from the singlet excited state of the host material to the singlet excited state of the fluorescent substance 132 is considered.

Next, an energy transfer by Dexter mechanism is considered. According to Formula (2), in order to increase the rate constant k_{h*→g}, it is preferable that an emission spectrum of the host material (a fluorescent spectrum in the case where energy transfer from a singlet excited state is discussed) largely overlap with an absorption spectrum of the fluorescent substance 132 (absorption corresponding to transition from a singlet ground state to a singlet excited state). Therefore, the energy transfer efficiency can be optimized by making the emission spectrum of the host material (i.e., the exciplex) overlap with the absorption band of the fluorescent substance 132 which is on the lowest energy side.

When Formula (2) is substituted into Formula (3), it is found that the energy transfer efficiency ϕ_{ET} in Dexter mechanism depends on τ. In Dexter mechanism, which is a process of energy transfer based on the electron exchange, as well as the energy transfer from the singlet excited state of the host material to the singlet excited state of the fluorescent substance 132, energy transfer from the triplet excited state of the host material to the triplet excited state of the fluorescent substance 132 occurs.

In the light-emitting element of one embodiment of the present invention in which the fluorescent substance 132 is a fluorescent material, the efficiency of energy transfer to the triplet excited state of the fluorescent substance 132 is preferably low. That is, the energy transfer efficiency based on Dexter mechanism from the host material to the fluorescent substance 132 is preferably low and the energy transfer efficiency based on Förster mechanism from the host material to the fluorescent substance 132 is preferably high.

As described above, the energy transfer efficiency in Förster mechanism does not depend on the lifetime τ of the excited state of the host material. In contrast, the energy transfer efficiency in Dexter mechanism depends on the excitation lifetime τ of the host material. To reduce the energy transfer efficiency in Dexter mechanism, the excitation lifetime τ of the host material is preferably short.

In a manner similar to that of the energy transfer from the host material to the fluorescent substance 132, it is considered that the energy transfer by both Förster mechanism and Dexter mechanism also occurs in the energy transfer process from the exciplex to the fluorescent substance 132.

Accordingly, one embodiment of the present invention provides a light-emitting element including, as an energy donor capable of efficiently transferring energy to the fluorescent substance 132, the host material including the first organic compound 131_1 and the second organic compound 131_2 which are a combination for forming an exciplex. The exciplex formed of the first organic compound 131_1 and the second organic compound 131_2 has a singlet excitation energy level and a triplet excitation energy level which are adjacent to each other; accordingly, transition from a triplet exciton generated in the light-emitting layer to a singlet exciton (reverse intersystem crossing) is likely to occur. This can increase the probability of generating singlet excitons in the light-emitting layer. Furthermore, it is preferable that an emission spectrum of the exciplex formed of the first organic compound 131_1 and the second organic compound 131_2 overlap with the absorption band of the fluorescent substance 132 having a function as an energy acceptor which is on the longest wavelength side (lowest energy side). This facilitates energy transfer from the singlet excited state of the exciplex to the singlet excited state of the fluorescent substance 132. Therefore, the probability of generating the singlet excited state of the fluorescent substance 132 can be increased. In addition, the fluorescent substance 132 includes at least two substituents that prevent the proximity to the exciplex, whereby the energy transfer efficiency from the triplet excited state of the exciplex to the triplet excited state of the fluorescent substance 132 can be reduced and the probability of generating the singlet excited state can be improved.

In addition, fluorescence lifetime of a thermally activated delayed fluorescence component in light emitted from the exciplex is preferably short, and specifically, preferably 10 ns or longer and 50 μs or shorter, further preferably 10 ns or longer and 40 μs or shorter, still further preferably 10 ns or longer and 30 μs or shorter.

The proportion of a thermally activated delayed fluorescence component in the light emitted from the exciplex is preferably high. Specifically, the proportion of a thermally activated delayed fluorescence component in the light emitted from the exciplex is preferably higher than or equal to 5%, further preferably higher than or equal to 10%, still further preferably higher than or equal to 20%.

The triplet excitation energy level of the exciplex is preferably higher than the triplet excitation energy level of each of the first organic compound and the second organic compound.

Note that triplet excitation energy of an exciplex, whose singlet excited state and triplet excited state has a small energy difference, can be considered equivalent to the emission wavelength of the exciplex.

Here, in the case where the first organic compound is a substance having a first skeleton including a benzofuropyrimidine skeleton or a benzothienopyrimidine skeleton, light can be emitted with extremely high efficiency.

The first organic compound is preferably a substance in which the first skeleton including a benzofuropyrimidine skeleton or a benzothienopyrimidine skeleton includes a benzofuro[3,2-d]pyrimidine skeleton or a benzothieno[3,2-d]pyrimidine skeleton. Since a benzene ring is introduced to the 6-position of pyrimidine in the skeleton, an electron-transport property is improved (that is, the first organic compound has higher electron-transport property than a hole-transport property). Furthermore, the first organic compound is preferable for formation of an exciplex because the LUMO level of the first organic compound is lower than that of pyrimidine.

The first skeleton of the first organic compound preferably includes a benzofuropyrimidine skeleton because a light-emitting element with higher emission efficiency can be obtained. Furthermore, the LUMO level of the first organic compound including a benzofuropyrimidine skeleton in the first skeleton is lower than the LUMO level of the first organic compound including a benzothienopyrimidine in the first skeleton. It is further preferable in the light-emitting element that the first skeleton be a benzofuro[3,2-d]pyrimidine skeleton.

The benzofuro[3,2-d] pyrimidine skeleton or the benzothieno[3,2-d]pyrimidine skeleton is preferably bonded to another skeleton at the 4-position. Accordingly, the 4-position and the 6-position of pyrimidine are substituted; thus, the electron-transport property is increased and the LUMO level becomes deep. That is, the first organic compound is suitable for formation of the exciplex.

The first organic compound preferably includes a second skeleton including any one of a carbazole skeleton, a dibenzothiophene skeleton, and a dibenzofuran skeleton in addition to the first skeleton. Note that in the case where the second skeleton includes a carbazole skeleton, the carbazole skeleton is preferably bonded to the first skeleton or the bivalent linking group connecting the first skeleton and the second skeleton at the 9-position. In the case where the second skeleton includes a dibenzothiophene or dibenzofuran skeleton, the dibenzothiophene or dibenzofuran skeleton is preferably bonded to the first skeleton or a bivalent linking group connecting the first skeleton and the second skeleton at the 4-position. Accordingly, an electrochemically stable compound can be obtained.

In the first organic compound, the first skeleton and the second skeleton are preferably connected via the bivalent linking group because formation of the exciplex formed of the first organic compound and the second organic compound is more likely to occur than a charge-transfer excited state in the first organic compound. In other words, the first skeleton and the second skeleton are physically apart from each other, so that the HOMO-LUMO transition between molecules (e.g., the transfer from the HOMO level of the second organic compound to the LUMO level of the first organic compound) is more likely to occur than the HOMO-LUMO transition in the molecule. The linking group is preferably a bivalent linking group having 6 to 60 carbon atoms. The linking group is further preferably an aromatic hydrocarbon group. Furthermore, the linking group still further preferably includes 6 to 13 carbon atoms because high sublimation property can be obtained. Considering the balance between separating the first skeleton from the second skeleton by the linking group and a sublimation property, a biphenyldiyl group is preferable as the linking group. A 3,3′-biphenyldiyl group is particularly preferable in terms of increasing the triplet excitation level.

Furthermore, the benzofuro[3,2-d]pyrimidine skeleton or the benzothieno[3,2-d]pyrimidine skeleton in the first skeleton is preferably bonded to the above linking group at the 4-position.

The second skeleton preferably includes a carbazole skeleton because the light-emitting element of this embodiment can emit light with more favorable efficiency. The 9-position of the second skeleton is preferably substituted. In particular, the second skeleton is further preferably a carbazole skeleton which bonds to the above linking group at the 9-position.

Specific examples of the first organic compound can be represented by Structural Formulae (100) to (114), Structural Formulae (200) to (205), Structural Formulae (300) to (311), Structural Formulae (400) to (414), Structural Formulae (500) to (505), and Structural Formulae (600) to (611). Note that the first organic compound that can be used in this embodiment is not limited to the following examples.

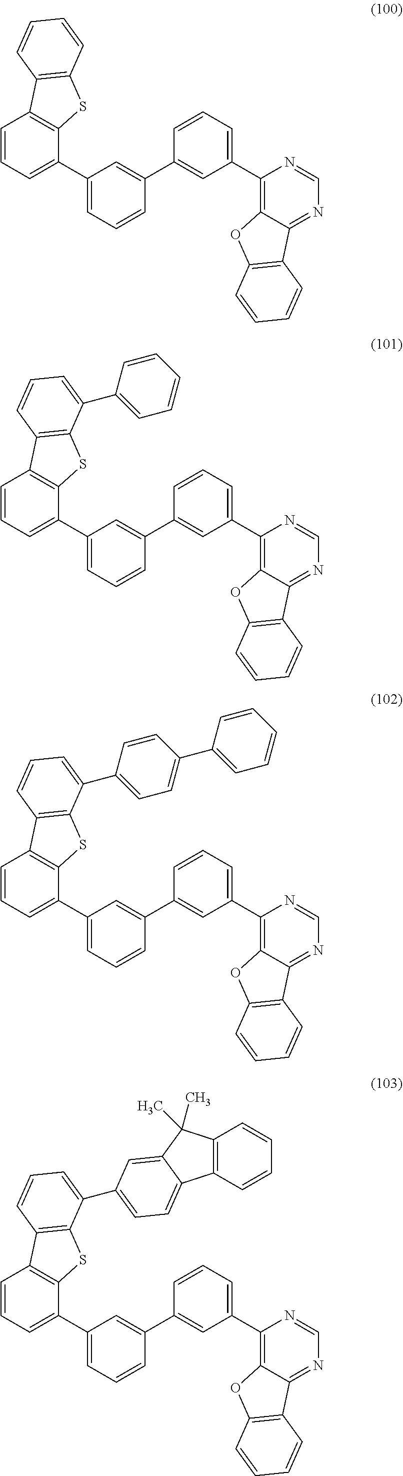

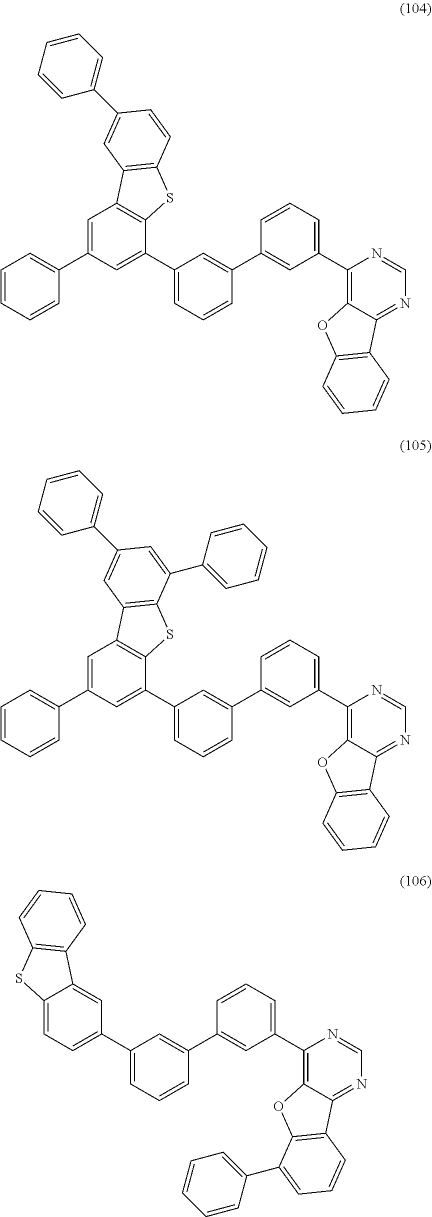 [SMILES: c1ccc(-c2ccc3sc4c(-c5cccc(-c6cccc(-c7ncnc8c7oc7ccccc78)c6)c5)cc(-c5ccccc5)cc4c3c2)cc1 ; c1ccc(-c2cc(-c3ccccc3)c3sc4c(-c5cccc(-c6cccc(-c7ncnc8c7oc7ccccc78)c6)c5)cc(-c5ccccc5)cc4c3c2)cc1 ; c1ccc(-c2cccc3c2oc2c(-c4cccc(-c5cccc(-c6ccc7sc8ccccc8c7c6)c5)c4)ncnc23)cc1]

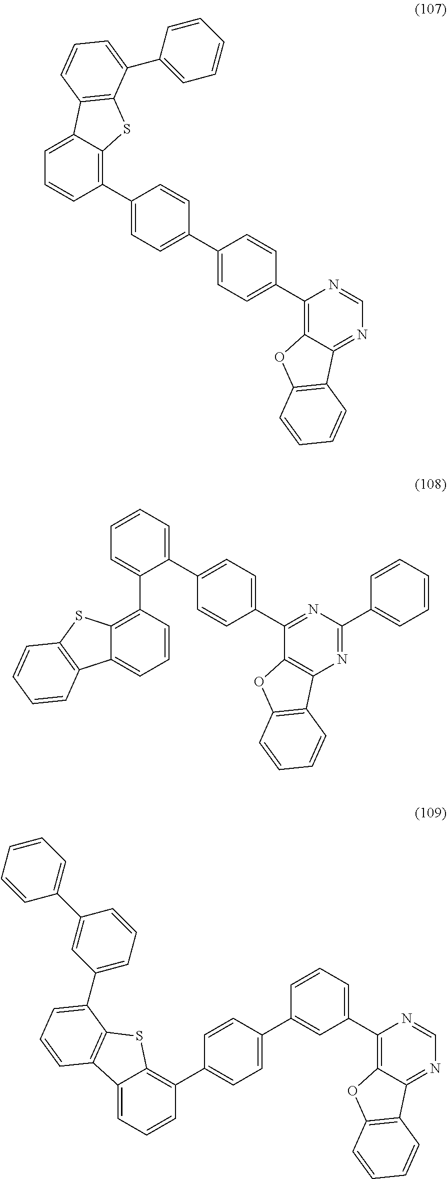 [SMILES: c1ccc(-c2cccc3c2sc2c(-c4ccc(-c5ccc(-c6ncnc7c6oc6ccccc67)cc5)cc4)cccc23)cc1 ; c1ccc(-c2nc(-c3ccc(-c4ccccc4-c4cccc5c4sc4ccccc45)cc3)c3oc4ccccc4c3n2)cc1 ; c1ccc(-c2cccc(-c3cccc4c3sc3c(-c5ccc(-c6cccc(-c7ncnc8c7oc7ccccc78)c6)cc5)cccc34)c2)cc1]

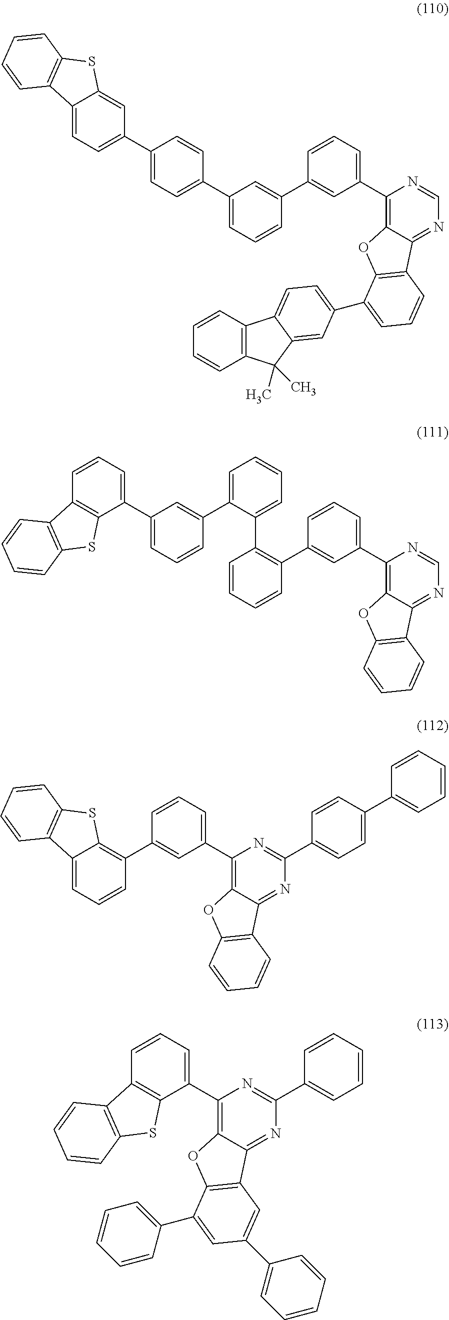 [SMILES: CC1(C)c2ccccc2-c2ccc(-c3cccc4c3oc3c(-c5cccc(-c6cccc(-c7ccc(-c8ccc9c(c8)sc8ccccc89)cc7)c6)c5)ncnc34)cc21 ; c1cc(-c2ccccc2-c2ccccc2-c2cccc(-c3cccc4c3sc3ccccc34)c2)cc(-c2ncnc3c2oc2ccccc23)c1 ; c1ccc(-c2ccc(-c3nc(-c4cccc(-c5cccc6c5sc5ccccc56)c4)c4oc5ccccc5c4n3)cc2)cc1 ; c1ccc(-c2cc(-c3ccccc3)c3oc4c(-c5cccc6c5sc5ccccc56)nc(-c5ccccc5)nc4c3c2)cc1]

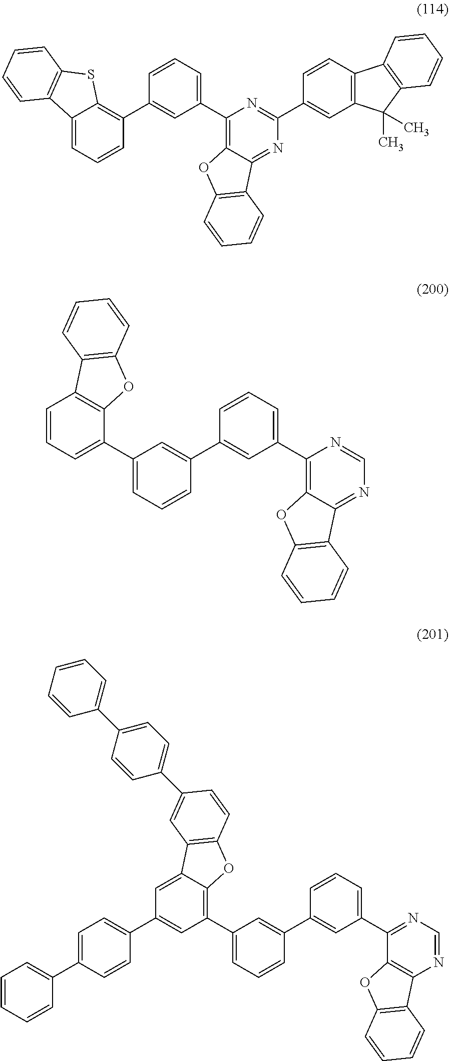 [SMILES: CC1(C)c2ccccc2-c2ccc(-c3nc(-c4cccc(-c5cccc6c5sc5ccccc56)c4)c4oc5ccccc5c4n3)cc21 ; c1cc(-c2cccc(-c3ncnc4c3oc3ccccc34)c2)cc(-c2cccc3c2oc2ccccc23)c1 ; c1ccc(-c2ccc(-c3ccc4oc5c(-c6cccc(-c7cccc(-c8ncnc9c8oc8ccccc89)c7)c6)cc(-c6ccc(-c7ccccc7)cc6)cc5c4c3)cc2)cc1]

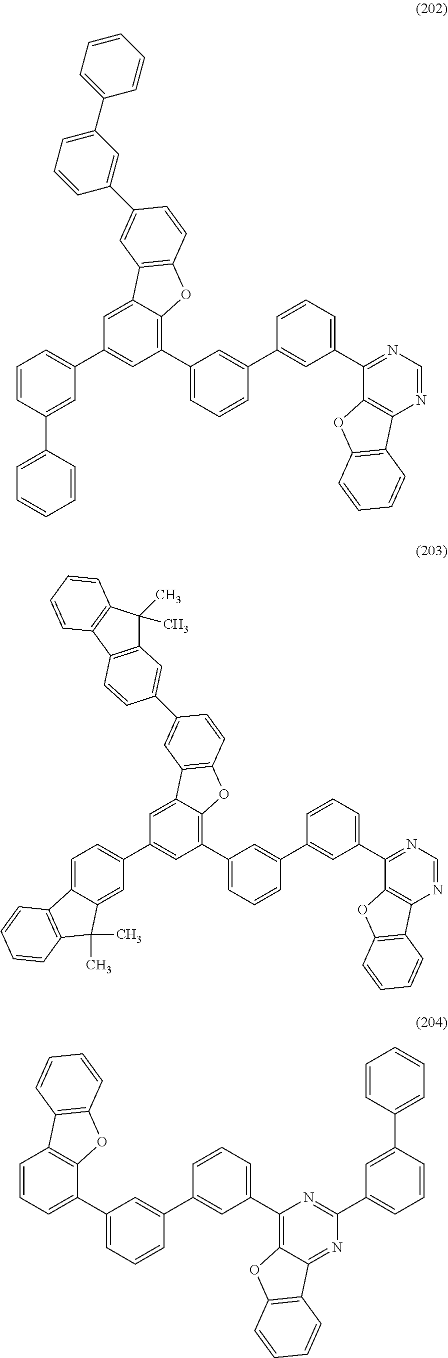 [SMILES: c1ccc(-c2cccc(-c3ccc4oc5c(-c6cccc(-c7cccc(-c8ncnc9c8oc8ccccc89)c7)c6)cc(-c6cccc(-c7ccccc7)c6)cc5c4c3)c2)cc1 ; CC1(C)c2ccccc2-c2ccc(-c3ccc4oc5c(-c6cccc(-c7cccc(-c8ncnc9c8oc8ccccc89)c7)c6)cc(-c6ccc7c(c6)C(C)(C)c6ccccc6-7)cc5c4c3)cc21 ; c1ccc(-c2cccc(-c3nc(-c4cccc(-c5cccc(-c6cccc7c6oc6ccccc67)c5)c4)c4oc5ccccc5c4n3)c2)cc1]

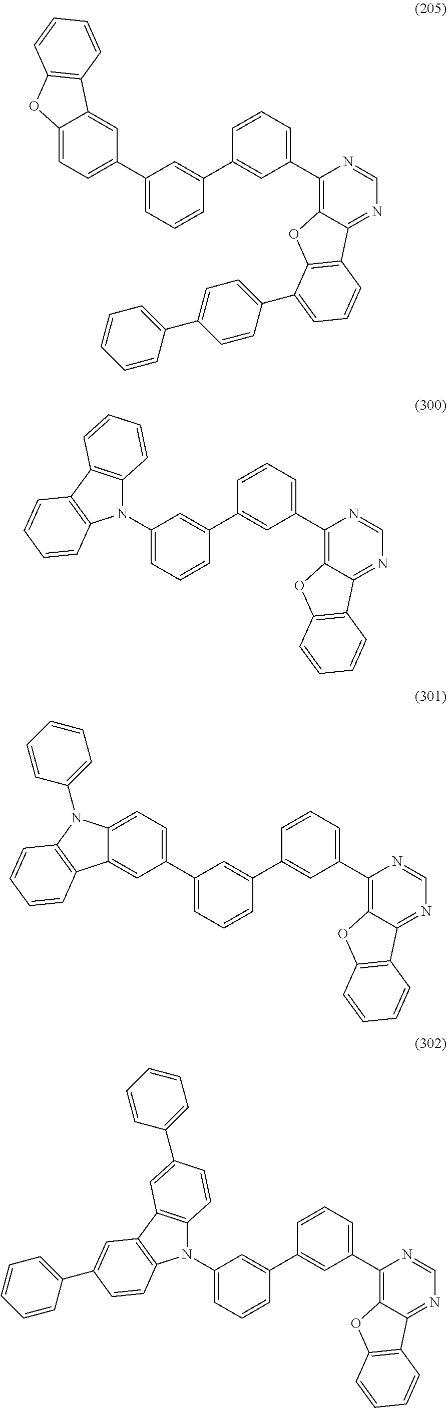 [SMILES: c1ccc(-c2ccc(-c3cccc4c3oc3c(-c5cccc(-c6cccc(-c7ccc8oc9ccccc9c8c7)c6)c5)ncnc34)cc2)cc1 ; c1cc(-c2cccc(-n3c4ccccc4c4ccccc43)c2)cc(-c2ncnc3c2oc2ccccc23)c1 ; c1ccc(-n2c3ccccc3c3cc(-c4cccc(-c5cccc(-c6ncnc7c6oc6ccccc67)c5)c4)ccc32)cc1 ; c1ccc(-c2ccc3c(c2)c2cc(-c4ccccc4)ccc2n3-c2cccc(-c3cccc(-c4ncnc5c4oc4ccccc45)c3)c2)cc1]

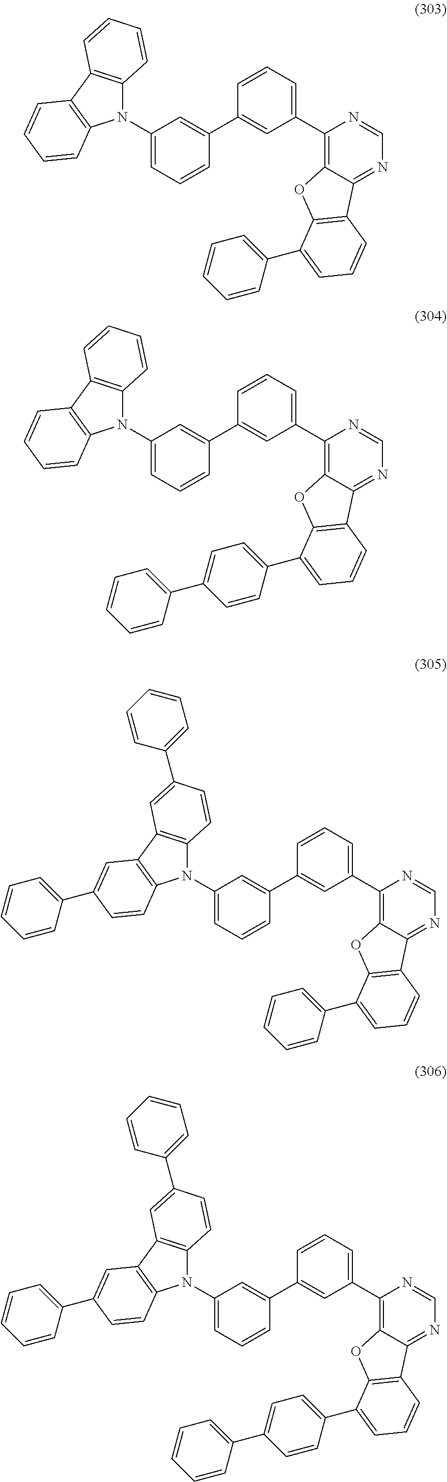 [SMILES: c1ccc(-c2cccc3c2oc2c(-c4cccc(-c5cccc(-n6c7ccccc7c7ccccc76)c5)c4)ncnc23)cc1 ; c1ccc(-c2ccc(-c3cccc4c3oc3c(-c5cccc(-c6cccc(-n7c8ccccc8c8ccccc87)c6)c5)ncnc34)cc2)cc1 ; c1ccc(-c2ccc3c(c2)c2cc(-c4ccccc4)ccc2n3-c2cccc(-c3cccc(-c4ncnc5c4oc4c(-c6ccccc6)cccc45)c3)c2)cc1 ; c1ccc(-c2ccc(-c3cccc4c3oc3c(-c5cccc(-c6cccc(-n7c8ccc(-c9ccccc9)cc8c8cc(-c9ccccc9)ccc87)c6)c5)ncnc34)cc2)cc1]

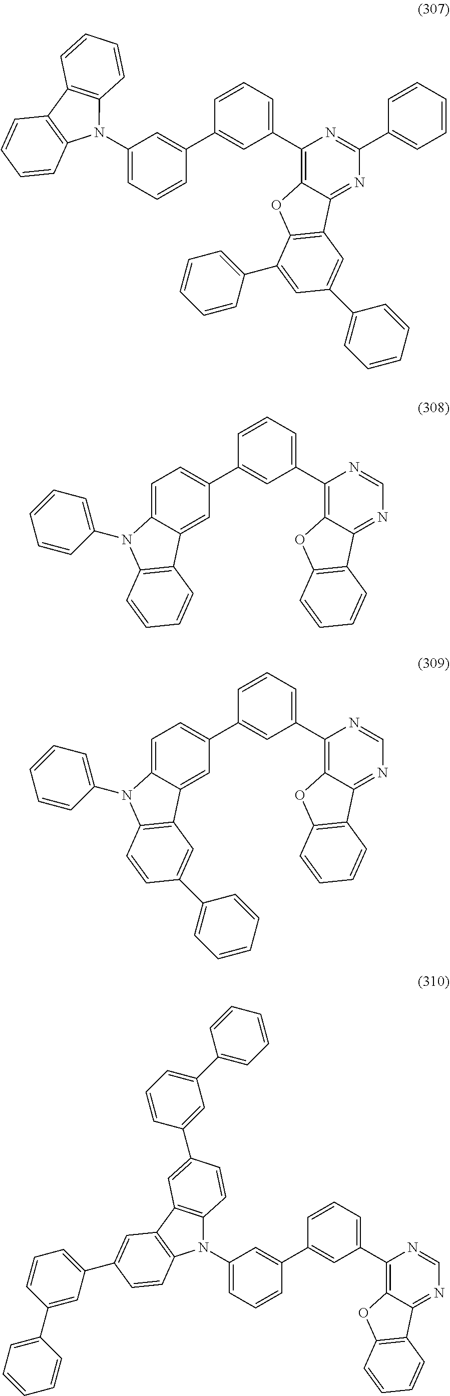 [SMILES: c1ccc(-c2cc(-c3ccccc3)c3oc4c(-c5cccc(-c6cccc(-n7c8ccccc8c8ccccc87)c6)c5)nc(-c5ccccc5)nc4c3c2)cc1 ; c1ccc(-n2c3ccccc3c3cc(-c4cccc(-c5ncnc6c5oc5ccccc56)c4)ccc32)cc1 ; c1ccc(-c2ccc3c(c2)c2cc(-c4cccc(-c5ncnc6c5oc5ccccc56)c4)ccc2n3-c2ccccc2)cc1 ; c1ccc(-c2cccc(-c3ccc4c(c3)c3cc(-c5cccc(-c6ccccc6)c5)ccc3n4-c3cccc(-c4cccc(-c5ncnc6c5oc5ccccc56)c4)c3)c2)cc1]

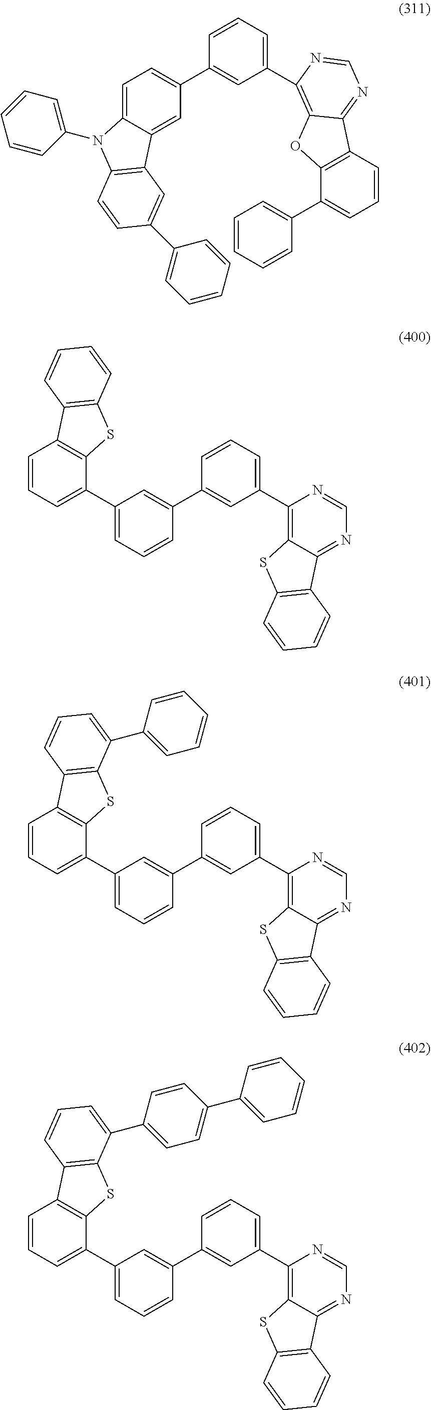

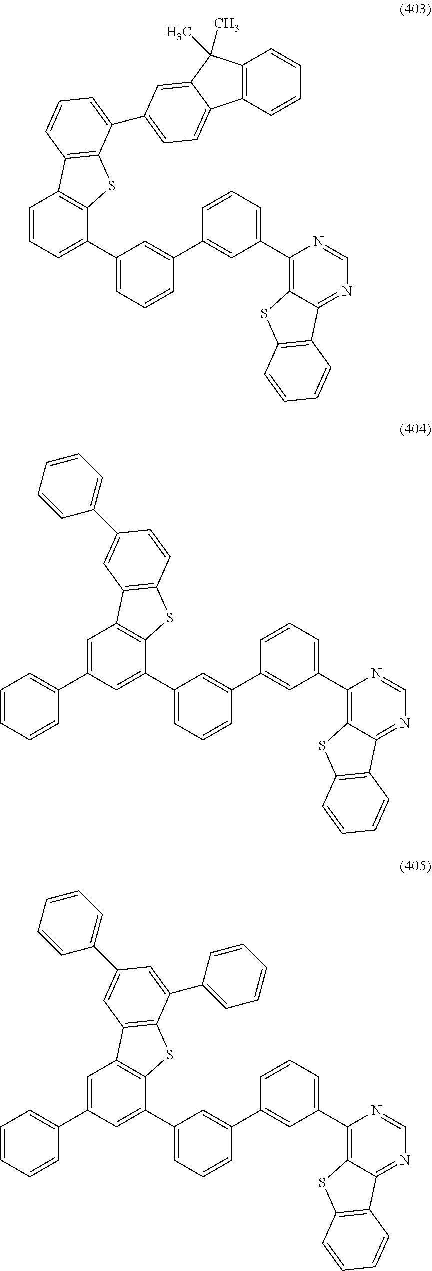 [SMILES: CC1(C)c2ccccc2-c2ccc(-c3cccc4c3sc3c(-c5cccc(-c6cccc(-c7ncnc8c7sc7ccccc78)c6)c5)cccc34)cc21 ; c1ccc(-c2ccc3sc4c(-c5cccc(-c6cccc(-c7ncnc8c7sc7ccccc78)c6)c5)cc(-c5ccccc5)cc4c3c2)cc1 ; c1ccc(-c2cc(-c3ccccc3)c3sc4c(-c5cccc(-c6cccc(-c7ncnc8c7sc7ccccc78)c6)c5)cc(-c5ccccc5)cc4c3c2)cc1]

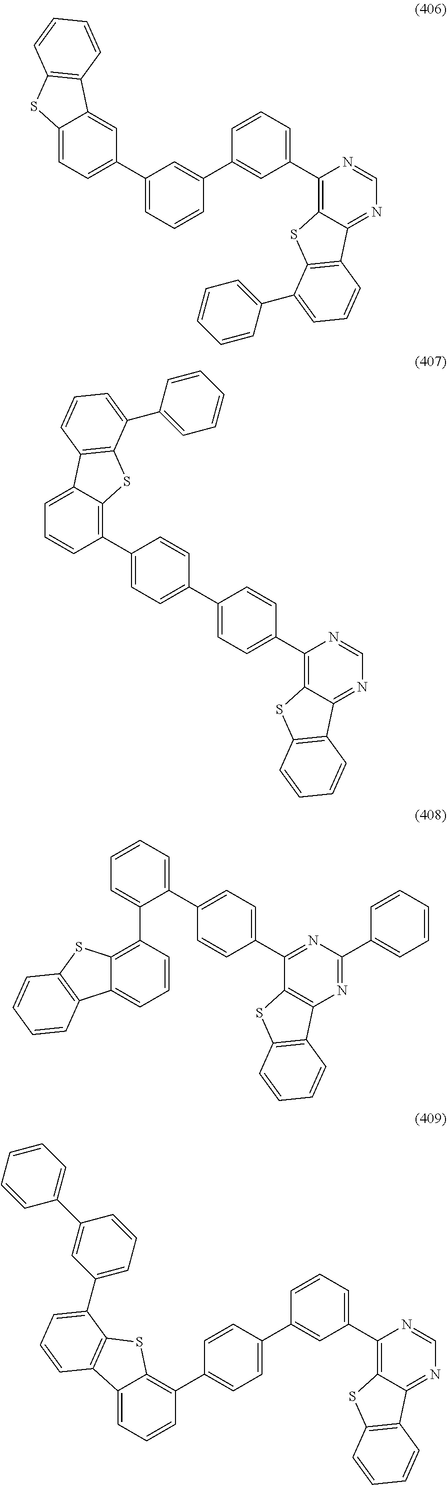

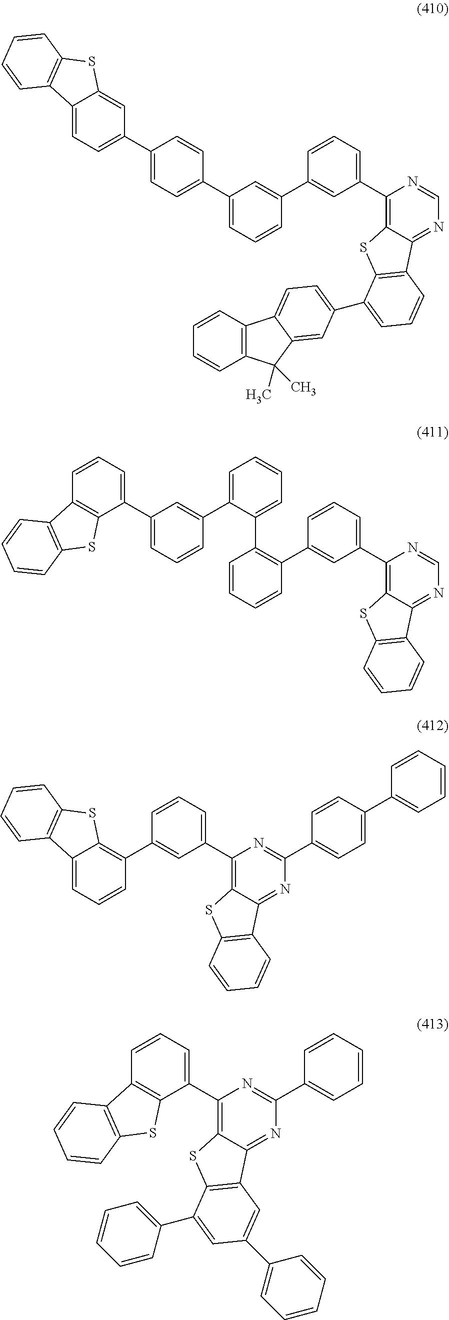 [SMILES: CC1(C)c2ccccc2-c2ccc(-c3cccc4c3sc3c(-c5cccc(-c6cccc(-c7ccc(-c8ccc9c(c8)sc8ccccc89)cc7)c6)c5)ncnc34)cc21 ; c1cc(-c2ccccc2-c2ccccc2-c2cccc(-c3ncnc4c3sc3ccccc34)c2)cc(-c2cccc3c2sc2ccccc23)c1 ; c1ccc(-c2ccc(-c3nc(-c4cccc(-c5cccc6c5sc5ccccc56)c4)c4sc5ccccc5c4n3)cc2)cc1 ; c1ccc(-c2cc(-c3ccccc3)c3sc4c(-c5cccc6c5sc5ccccc56)nc(-c5ccccc5)nc4c3c2)cc1]

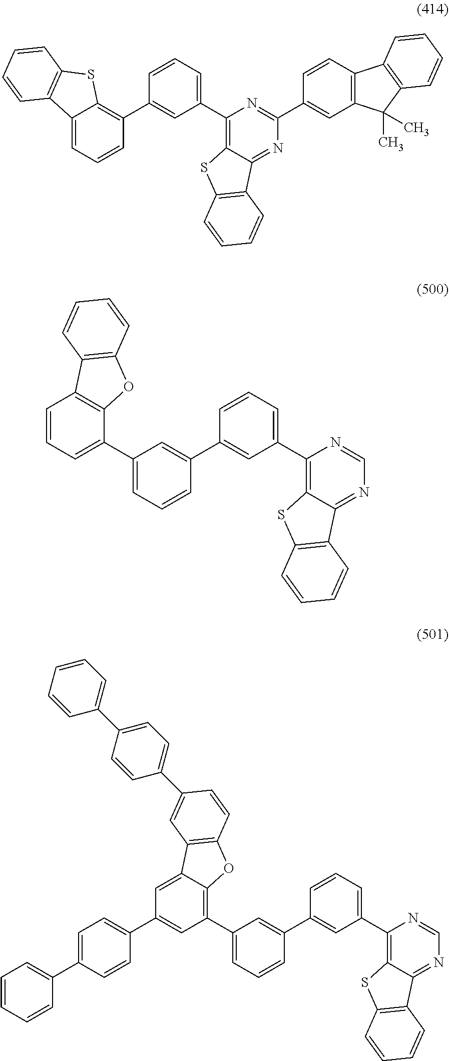 [SMILES: CC1(C)c2ccccc2-c2ccc(-c3nc(-c4cccc(-c5cccc6c5sc5ccccc56)c4)c4sc5ccccc5c4n3)cc21 ; c1cc(-c2cccc(-c3ncnc4c3sc3ccccc34)c2)cc(-c2cccc3c2oc2ccccc23)c1 ; c1ccc(-c2ccc(-c3ccc4oc5c(-c6cccc(-c7cccc(-c8ncnc9c8sc8ccccc89)c7)c6)cc(-c6ccc(-c7ccccc7)cc6)cc5c4c3)cc2)cc1]

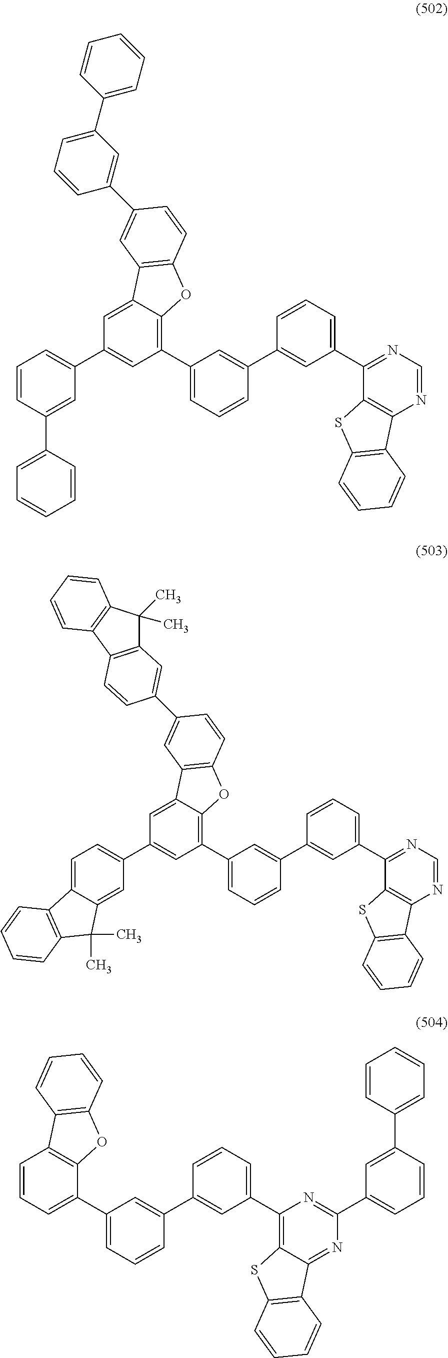 [SMILES: c1ccc(-c2cccc(-c3ccc4oc5c(-c6cccc(-c7cccc(-c8ncnc9c8sc8ccccc89)c7)c6)cc(-c6cccc(-c7ccccc7)c6)cc5c4c3)c2)cc1 ; CC1(C)c2ccccc2-c2ccc(-c3ccc4oc5c(-c6cccc(-c7cccc(-c8ncnc9c8sc8ccccc89)c7)c6)cc(-c6ccc7c(c6)C(C)(C)c6ccccc6-7)cc5c4c3)cc21 ; c1ccc(-c2cccc(-c3nc(-c4cccc(-c5cccc(-c6cccc7c6oc6ccccc67)c5)c4)c4sc5ccccc5c4n3)c2)cc1]

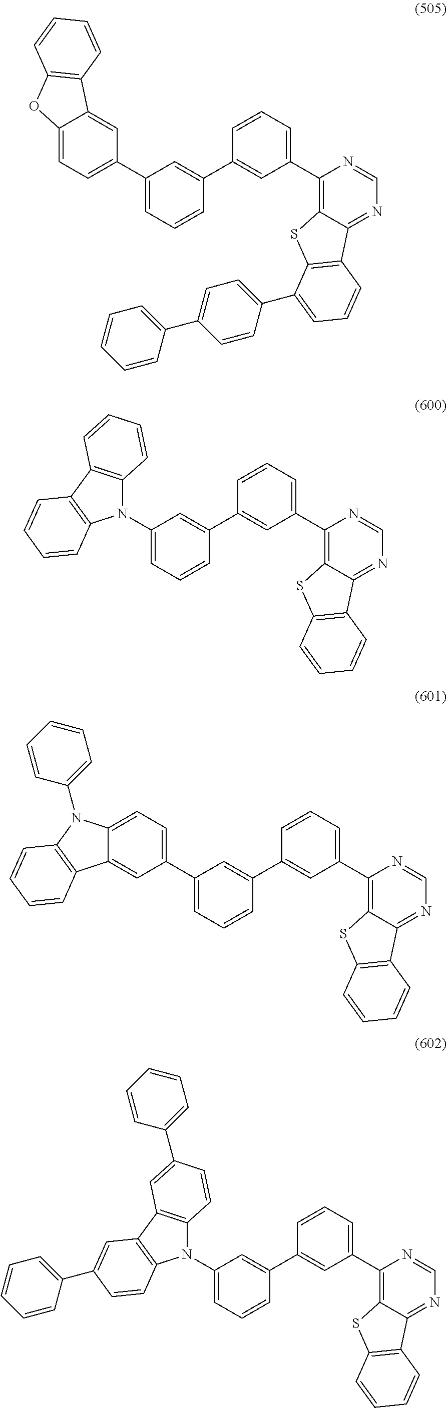 [SMILES: c1ccc(-c2ccc(-c3cccc4c3sc3c(-c5cccc(-c6cccc(-c7ccc8oc9ccccc9c8c7)c6)c5)ncnc34)cc2)cc1 ; c1cc(-c2cccc(-n3c4ccccc4c4ccccc43)c2)cc(-c2ncnc3c2sc2ccccc23)c1 ; c1ccc(-n2c3ccccc3c3cc(-c4cccc(-c5cccc(-c6ncnc7c6sc6ccccc67)c5)c4)ccc32)cc1 ; c1ccc(-c2ccc3c(c2)c2cc(-c4ccccc4)ccc2n3-c2cccc(-c3cccc(-c4ncnc5c4sc4ccccc45)c3)c2)cc1]

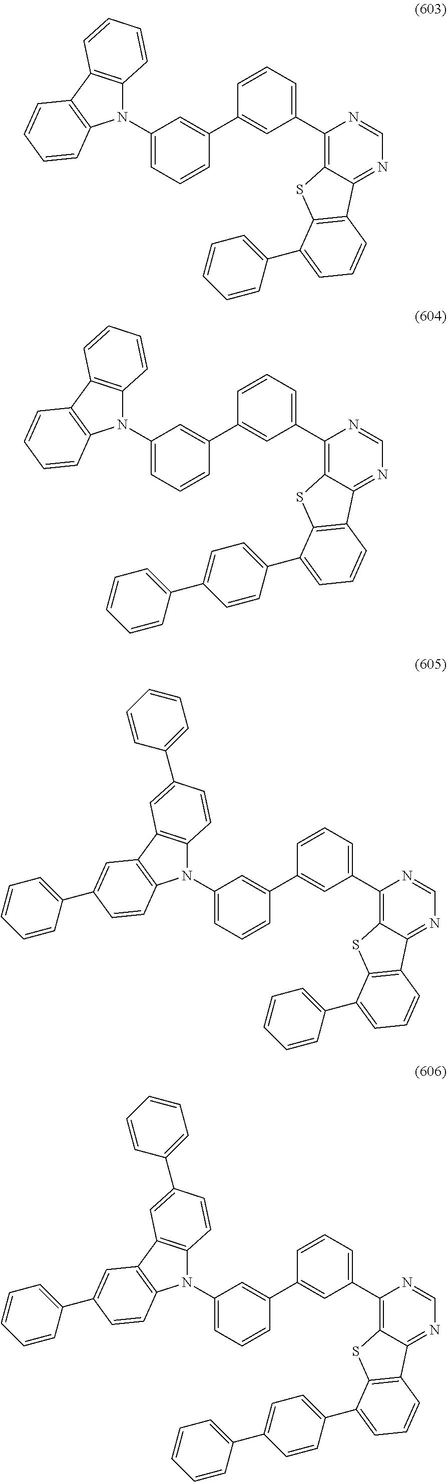 [SMILES: c1ccc(-c2cccc3c2sc2c(-c4cccc(-c5cccc(-n6c7ccccc7c7ccccc76)c5)c4)ncnc23)cc1 ; c1ccc(-c2ccc(-c3cccc4c3sc3c(-c5cccc(-c6cccc(-n7c8ccccc8c8ccccc87)c6)c5)ncnc34)cc2)cc1 ; c1ccc(-c2ccc3c(c2)c2cc(-c4ccccc4)ccc2n3-c2cccc(-c3cccc(-c4ncnc5c4sc4c(-c6ccccc6)cccc45)c3)c2)cc1 ; c1ccc(-c2ccc(-c3cccc4c3sc3c(-c5cccc(-c6cccc(-n7c8ccc(-c9ccccc9)cc8c8cc(-c9ccccc9)ccc87)c6)c5)ncnc34)cc2)cc1]

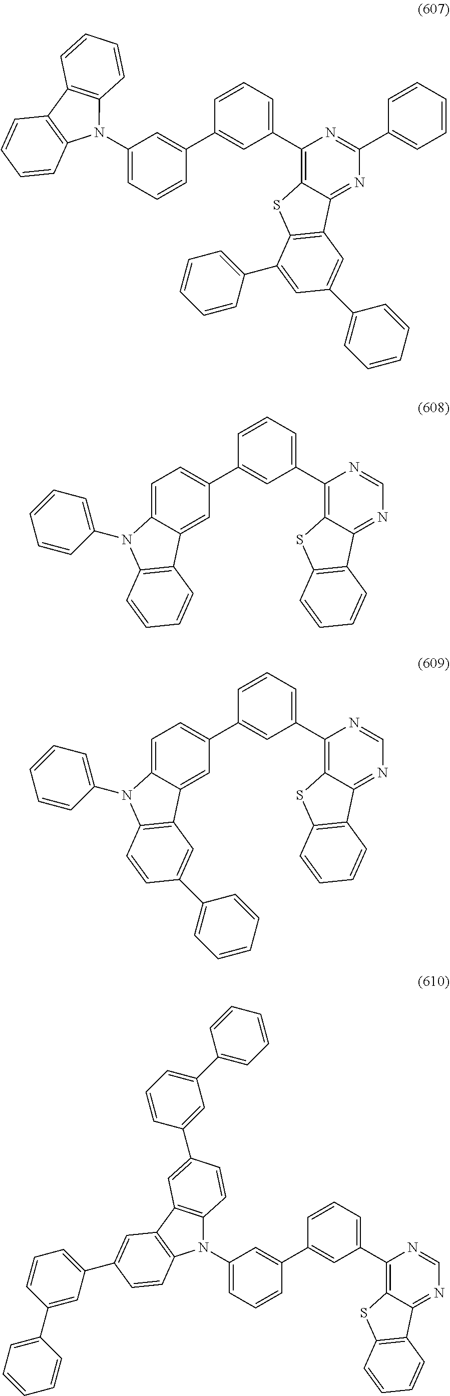 [SMILES: c1ccc(-c2cc(-c3ccccc3)c3sc4c(-c5cccc(-c6cccc(-n7c8ccccc8c8ccccc87)c6)c5)nc(-c5ccccc5)nc4c3c2)cc1 ; c1ccc(-n2c3ccccc3c3cc(-c4cccc(-c5ncnc6c5sc5ccccc56)c4)ccc32)cc1 ; c1ccc(-c2ccc3c(c2)c2cc(-c4cccc(-c5ncnc6c5sc5ccccc56)c4)ccc2n3-c2ccccc2)cc1 ; c1ccc(-c2cccc(-c3ccc4c(c3)c3cc(-c5cccc(-c6ccccc6)c5)ccc3n4-c3cccc(-c4cccc(-c5ncnc6c5sc5ccccc56)c4)c3)c2)cc1]

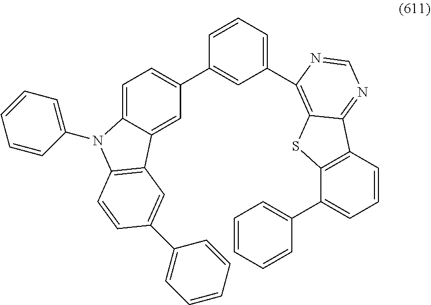 [SMILES: c1ccc(-c2ccc3c(c2)c2cc(-c4cccc(-c5ncnc6c5sc5c(-c7ccccc7)cccc56)c4)ccc2n3-c2ccccc2)cc1]

In the case where the first organic compound including the benzofuropyrimidine skeleton or the benzothienopyrimidine skeleton is a substance which has an electron-transport property, the second organic compound is preferably a substance having a hole-transport property because formation of an exciton is facilitated. At this time, the second organic compound is further preferably a substance including a π-electron rich heteroaromatic ring skeleton or an aromatic amine skeleton.

The second organic compound is preferably a substance in which a hole-transport property is higher than an electron-transport property, and a hole-transport material having a hole mobility of 10⁻⁶ cm²/Vs or more can be mainly used. Specifically, a π-electron rich heteroaromatic compound such as a carbazole derivative or an indole derivative and an aromatic amine compound are preferable and examples include compounds having aromatic amine skeletons, such as 2-[N-(9-phenylcarbazol-3-yl)-N-phenylamino]spiro-9,9′-bifluorene (abbreviation: PCASF), 4,4′,4″-tris [N-(1-naphthyl)-N-phenylamino]triphenylamine (abbreviation: 1′-TNATA), 2,7-bis[N-(4-diphenylaminophenyl)-N-phenylamino]-spiro-9,9′-bifluorene (abbreviation: DPA2SF), N,N′-bis(9-phenylcarbazol-3-yl)-N,N′-diphenylbenzene-1,3-diamine (abbreviation: PCA2B), N-(9,9-dimethyl-2-diphenylamino-9H-fluoren-7-yl)diphenylamine (abbreviation: DPNF), N,N′,N″-triphenyl-N,N′,N″-tris(9-phenylcarbazol-3-yl)benzene-1,3,5-triamine (abbreviation: PCA3B), 2-[N-(4-diphenylaminophenyl)-N-phenylamino]spiro-9,9′-bifluorene (abbreviation: DPASF), N,N′-bis[4-(carbazol-9-yl)phenyl]-N,N′-diphenyl-9,9-dimethylfluorene-2,7-diamine (abbreviation: YGA2F), NPB, N,N′-bis(3-methylphenyl)-N,N′-diphenyl[1,1′-biphenyl]-4,4′-diamine (abbreviation: TPD), 4,4′-bis[N-(4-diphenylaminophenyl)-N-phenylamino]biphenyl (abbreviation: DPAB), BSPB, 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), PCzPCA1, 3-[N-(4-diphenylaminophenyl)-N-phenylamino]-9-phenylcarbazole (abbreviation: PCzDPA1), 3,6-bis [N-(4-diphenylaminophenyl)-N-phenylamino]-9-phenylcarbazole (abbreviation: PCzDPA2), DNTPD, 3,6-bis [N-(4-diphenylaminophenyl)-N-(1-naphthyl)amino]-9-phenylcarbazole (abbreviation: PCzTPN2), and PCzPCA2, 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 3-[N-(1-naphthyl)-N-(9-phenylcarbazol-3-yl)amino]-9-phenylcarbazole (abbreviation: PCzPCN1), 9,9-dimethyl-N-phenyl-N-[4-(9-phenyl-9H-carbazol-3-yl)phenyl]-fluoren-2-amine (abbreviation: PCBAF), N-phenyl-N-[4-(9-phenyl-9H-carbazol-3-yl)phenyl]-spiro-9,9′-bifluoren-2-amine (abbreviation: PCBASF), N-(4-biphenyl)-N-(9,9-dimethyl-9H-fluoren-2-yl)-9-phenyl-9H-carbazol-3-amine (abbreviation: PCBiF), and N-(1,1′-biphenyl-4-yl)-N-[4-(9-phenyl-9H-carbazol-3-yl)phenyl]-9,9-dimethyl-9H-fluoren-2-amine (abbreviation: PCBBiF); compounds having carbazole skeletons, such as 1,3-bis(N-carbazolyl)benzene (abbreviation: mCP), CBP, 3,6-bis(3,5-diphenylphenyl)-9-phenylcarbazole (abbreviation: CzTP), and 9-phenyl-9H-3-(9-phenyl-9H-carbazol-3-yl)carbazole (abbreviation: PCCP); compounds having thiophene skeletons, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having furan skeletons, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties to contribute to a reduction in drive voltage.

As the fluorescent substance, any of the following substances can be used, for example. Fluorescent substances other than those given below can also be used. Examples of the fluorescent substance are 5,6-bis[4-(10-phenyl-9-anthryl)phenyl]-2,2′-bipyridine (abbreviation: PAP2BPy), 5,6-bis [4′-(10-phenyl-9-anthryl)iphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis [3-(9-phenyl-9H-fluoren-9-yl)phenyl]-pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N- [4-(10-phenyl-9-anthry)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis [N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′41 ,N′″-octahenyldibenzo,pchhysene-271015-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 2,8-di-tert-butyl-5,11-bis(4-tert-butylphenyl)-6,12-diphenyltetracene (abbreviation: TBRb), 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo [ij]quinolizin-9-yl)ethenyl]-4H-pyran-4-ylidene}propanedinitrile (abbreviation: DCM2), N,N,N′,N′-tetrakis(4-methylpheny)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij] quinolizin-9-yl)ethenyl]-4H-pyran-4-ylidene}propanedinitrile (abbreviation: DCJTI), 2- {2-tert-butyl-6-[2-(1,1,7,7-tetramethyl-2,3,6,7-tetrahydro-1H,5H-benzo [ij] quinolizin-9-yl)ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene)propanedinitrile (abbreviation: BisDCM), 2- {2,6-bis [2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and the like. Condensed aromatic diamine compounds typified by pyrenediamine compounds such as 1,6FLPAPrn and 1,6mMemFLPAPrn are particularly preferable because of their high hole-trapping properties, high emission efficiency, and high reliability.

Note that, as described above, the energy transfer efficiency from the host material (or the exciplex) to the fluorescent substance 132 by Dexter mechanism is preferably low. The rate constant of Dexter mechanism is inversely proportional to the exponential function of the distance between the two molecules. In general, when the distance between the two molecules is 1 nm or less, Dexter mechanism is dominant, and when the distance is 1 nm or more, Förster mechanism is dominant. To reduce the energy transfer efficiency in Dexter mechanism, the distance between the host material and the fluorescent substance 132 is preferably large, and specifically, 0.7 nm or more, further preferably 0.9 nm or more, still further preferably 1 nm or more. From such a point of view, the fluorescent substance 132 preferably includes a substituent that prevents the proximity to the host material. The substituent is preferably aliphatic hydrocarbon, further preferably an alkyl group, still further preferably a branched alkyl group. Specifically, the fluorescent substance 132 preferably includes at least two alkyl groups each having 2 or more carbon atoms. Alternatively, the fluorescent substance 132 preferably includes at least two branched alkyl groups each having 3 to 10 carbon atoms. Alternatively, the fluorescent substance 132 preferably includes at least two cycloalkyl groups each having 3 to 10 carbon atoms. Specifically, TBRb and TBP which are listed above can be given.

The fluorescent light-emitting element having the above-described structure emits light with extremely high efficiency. Although the theoretical limit of external quantum efficiency of a fluorescent light-emitting element is generally considered to be 5% to 7% when it is not designed to enhance extraction efficiency, a light-emitting element having external quantum efficiency much higher than the theoretical limit can be easily provided with the use of the structure of the light-emitting element in this embodiment.

Furthermore, since the exciplex has a singlet excitation energy level corresponding to a difference between a higher HOMO level and a lower LUMO level of the first and second organic compounds that form the exciplex as described above, a light-emitting element capable of efficient energy transfer to a desired fluorescent substance can be easily obtained by selection of substances each of which has an appropriate level.

In this manner, the structure in this embodiment makes it possible to easily obtain a high-efficiency light-emitting element in which a triplet excited state can be converted into light emission without using a rare metal the supply of which is unstable. Besides, light-emitting elements with such characteristics can be provided without severe limitation on their emission wavelengths.

### Embodiment 2

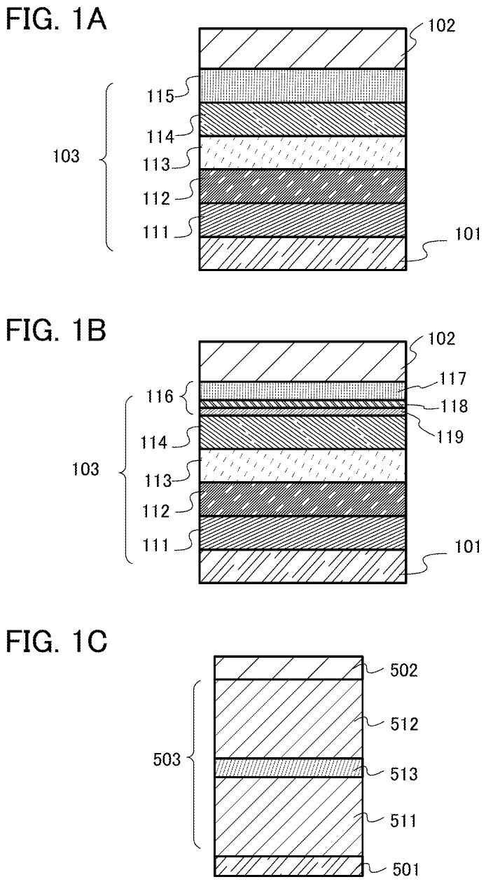

In this embodiment, a detailed example of the structure of the light-emitting element described in Embodiment 1 will be described below with reference to FIGS. 1A and 1B.

In FIG. 1A, the light-emitting element includes a first electrode 101, a second electrode 102, and a layer 103 containing organic compounds and provided between the first electrode 101 and the second electrode 102. Note that in this embodiment, the following description is made on the assumption that the first electrode 101 functions as an anode and that the second electrode 102 functions as a cathode.

To function as an anode, the first electrode 101 is preferably formed using any of metals, alloys, conductive compounds having a high work function (specifically, a work function of 4.0 eV or more), mixtures thereof, and the like. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is deposited by a sputtering method using a target obtained by adding 1 wt % to 20 wt % of zinc oxide to indium oxide. Furthermore, a film of indium oxide containing tungsten oxide and zinc oxide (IWZO) can be formed by a sputtering method using a target in which tungsten oxide and zinc oxide are added to indium oxide at 0.5 wt % to 5 wt % and 0.1 wt % to 1 wt %, respectively. Alternatively, gold (Au), platinum (Pt), nickel (Ni), tungsten (W), chromium (Cr), molybdenum (Mo), iron (Fe), cobalt (Co), copper (Cu), palladium (Pd), nitride of a metal material (e.g., titanium nitride), or the like can be used. Graphene can also be used. Note that when a composite material described later is used for a layer which is in contact with the first electrode 101 in the layer 103 containing organic compounds, an electrode material can be selected regardless of its work function.

There is no particular limitation on the stacked structure of the layer 103 containing organic compounds as long as the light-emitting layer 113 has the structure described in Embodiment 1. For example, in FIG. 1A, the layer 103 containing organic compounds can be formed by combining a hole-injection layer, a hole-transport layer, the light-emitting layer, an electron-transport layer, an electron-injection layer, a carrier-blocking layer, a charge-generation layer, and the like as appropriate. In this embodiment, the layer 103 containing organic compounds has a structure in which a hole-injection layer 111, a hole-transport layer 112, a light-emitting layer 113, an electron-transport layer 114, and an electron-injection layer 115 are stacked in this order from the first electrode 101 side. Materials for forming each layer are specifically shown below.

The hole-injection layer 111 is a layer containing a substance having a hole-injection property. For example, a transition metal oxide, particularly an oxide of a metal belonging to Group 4 to Group 8 in the periodic table (e.g., a molybdenum oxide, a vanadium oxide, a ruthenium oxide, a rhenium oxide, a tungsten oxide, or a manganese oxide) or the like can be used. Alternatively, a complex of a transition metal or a complex of a metal belonging to Group 4 to Group 8 in the periodic table can be used; for example, a molybdenum complex such as molybdenum tris[1,2-bis(trifluoromethyl)ethane-1,2-dithiolene] (abbreviation: Mo(tfd)₃) can be used. The transition metal oxide, the oxide of a metal belonging to Group 4 to Group 8 in the periodic table, or the complex of a transition metal or the complex of a metal belonging to Group 4 to Group 8 in the periodic table acts as an acceptor. The acceptor can extract an electron from the hole-transport layer 112 (or a hole-transport material) adjacent to the hole-injection layer 111 by at least application of an electric field. Further alternatively, a compound including an electron-withdrawing group (a halogen group or a cyano group) such as 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, or 2,3,6,7,10,11-hexacyano-1,4,5,8,9,12-hexaazatriphenylene (abbreviation: HAT-CN) can be used. Alternatively, the hole-injection layer 111 can be formed using a phthalocyanine-based compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis {4-[bis(3-methylphenyl)amino]phenyl}-N,N′-diphenyl-(1,1′-biphenyl)-4,4′-diamine (abbreviation: DNTPD), a high molecular compound such as poly(3,4-ethylenedioxythiophene)/poly(styrenesulfonic acid) (PEDOT/PSS), or the like.

Alternatively, a composite material in which a substance having a hole-transport property contains a substance having an acceptor property can be used for the hole-injection layer 111. Note that the use of such a substance having a hole-transport property which contains a substance having an acceptor property enables selection of a material used to form an electrode regardless of its work function. In other words, besides a material having a high work function, a material having a low work function can also be used for the first electrode 101. Examples of the acceptor material include a compound including an electron-withdrawing group (a halogen group or a cyano group) such as F₄-TCNQ, chloranil, or HAT-CN, a transition metal oxide, an oxide of a metal belonging to Group 4 to Group 8 in the periodic table, and the like. A transition metal oxide and an oxide of a metal belonging to Group 4 to Group 8 in the periodic table is preferred because these oxides show an acceptor property with respect to a substance having a hole-transport property whose HOMO level is lower (deeper) than −5.4 eV (these oxides can extract an electron by at least application of an electric field).

As the compound including an electron-withdrawing group (a halogen group or a cyano group), a compound in which an electron-withdrawing group is bonded to a condensed aromatic ring including a plurality of heteroatoms such as HAT-CN is particularly preferred because of its thermal stability.

As the transition metal oxide or the oxide of a metal belonging to Group 4 to Group 8 in the periodic table, vanadium oxide, niobium oxide, tantalum oxide, chromium oxide, molybdenum oxide, tungsten oxide, manganese oxide, and rhenium oxide are preferable because of their high acceptor properties. In particular, molybdenum oxide is more preferable because of its stability in the atmosphere, low hygroscopic property, and easiness of handling.

As the substance having a hole-transport property which is used for the composite material, any of a variety of organic compounds such as aromatic amine compounds, carbazole derivatives, aromatic hydrocarbons, and high molecular compounds (e.g., oligomers, dendrimers, or polymers) can be used. Note that the organic compound used for the composite material is preferably an organic compound having a high hole-transport property. Specifically, a substance having a hole mobility of 10⁻⁶ cm²/Vs or more is preferably used. Examples of organic compounds that can be used as the substance having a hole-transport property in the composite material are specifically given below.

Examples of the aromatic amine compounds that can be used for the composite material are N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), and the like. Specific examples of carbazole derivatives are 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris [4-(N-carbazolyl)phenyl]benzene (abbreviation: TCPB), 9-[4-(10-phenyl-9-anthracenyl)phenyl]-9H-carbazole (abbreviation: CzPA), 1,4-bis [4-(N-carbazolyl)phenyl]-2,3,5,6-tetraphenylbenzene, and the like. Examples of the aromatic hydrocarbons are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tent-butyl-9,10-bis [2-(1-naphthyl)phenyl]anthracene, 9,10-bis [2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis [(2,3,4,5,6-pentaphenyl)phenyl]-9,9′-bianthryl, anthracene, tetracene, rubrene, perylene, 2,5,8,11-tetra(tert-butyl)perylene, and the like. Besides, pentacene, coronene, or the like can also be used. The aromatic hydrocarbons may have a vinyl skeleton. As aromatic hydrocarbon having a vinyl group, the following is given, for example: 4,4′-bis(2,2-diphenylvinyl)biphenyl (abbreviation: DPVBi); 9,10-bis [4-(2,2-diphenylvinyl)phenyl]anthracene (abbreviation: DPVPA); and the like.

Moreover, a high molecular compound such as poly(N-vinylcarbazole) (abbreviation: PVK), poly(4-vinyltriphenylamine) (abbreviation: PVTPA), poly [N-(4-{N′-[4-(4-diphenylamino)phenyl]phenyl-N′-phenylamino}phenyl)methacrylamide] (abbreviation: PTPDMA), or poly [N,N′-bis(4-butylphenyl)-N,N′-bis(phenyl)benzidine (abbreviation: Poly-TPD) can also be used.

By providing a hole-injection layer, a high hole-injection property can be achieved to allow a light-emitting element to be driven at a low voltage.

Note that the hole-injection layer may be formed of the above-described acceptor material alone or of the above-described acceptor material and another material in combination. In this case, the acceptor material extracts electrons from the hole-transport layer, so that holes can be injected into the hole-transport layer. The acceptor material transfers the extracted electrons to the anode.

The hole-transport layer 112 is a layer containing a substance having a hole-transport property. Examples of the substance having a hole-transport property are aromatic amine compounds such as 4,4′-bis[N-(1-naphthyl)-N-phenylamino]biphenyl (abbreviation: NPB), N,N′-bis(3-methylphenyl)-N,N′-diphenyl-[4,4′-biphenyl]-4,4′-diamine (abbreviation: TPD), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis [N-(spiro-9,9′-bifluoren-2-yl)-N-phenylamino]biphenyl (abbreviation: BSPB), and 4-phenyl-4′-(9-phenylfluoren-9-yl)triphenylamine (abbreviation: BPAFLP). The substances listed here have high hole-transport properties and are mainly ones that have a hole mobility of 10⁻⁶ cm²/Vs or higher. An organic compound given as an example of the substance having a hole-transport property in the composite material described above can also be used for the hole-transport layer 112. Moreover, a high molecular compound such as poly(N-vinylcarbazole) (abbreviation: PVK) and poly(4-vinyltriphenylamine) (abbreviation: PVTPA) can also be used. Note that the layer that contains a substance having a hole-transport property is not limited to a single layer, and may be a stack of two or more layers including any of the above substances.

The light-emitting layer 113 is a layer including the first organic compound, the second organic compound, and a fluorescent substance. Materials and structures of the compounds are as described in Embodiment 1. By having such a structure, the light-emitting element of this embodiment has extremely high external quantum efficiency though it is a fluorescent light-emitting element that does not use a rare metal. The light-emitting element also has an advantage in that its emission wavelength can be easily adjusted and thus light in desired wavelength ranges can be easily obtained with the efficiency kept high.

The electron-transport layer 114 is a layer containing a material having an electron-transport property. Examples include a metal complex such as bis(10-hydroxybenzo[h]quinolinato)beryllium(II) (abbreviation: BeBq2), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); a heterocyclic compound having a polyazole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), a heterocyclic compound having a diazine skeleton, such as 2[3-(dibenzothiophen-4-yl)phenyl]dibenzo[f,h]quinoxaline (abbreviation: 2mDBTPDBq-II), 2-[3-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h] quinoxaline (abbreviation: 2mCzBPDBq), 4,6-bis [3-(phenanthren-9-yl)phenyl]pyrimidine (abbreviation: 4,6mPnP2Pm), or 4,6-bis [3-(4-dibenzothienyl)phenyl]pyrimidine (abbreviation: 4,6mDBTP2Pm-II); and a heterocyclic compound having a pyridine skeleton, such as, 3,5-bis[3-(9H-carbazol-9-yl)phenyl]pyridine (abbreviation: 35DCzPPy), or 1,3,5-tri [3-(3-pyridyl)phenyl]benzene (abbreviation: TmPyPB). Among the above materials, a heterocyclic compound having a diazine skeleton and a heterocyclic compound having a pyridine skeleton have high reliability and are thus preferable. Specifically, a heterocyclic compound having a diazine (pyrimidine or pyrazine) skeleton has a high electron-transport property to contribute to a reduction in drive voltage. The substances mentioned here have high electron-transport properties and are mainly ones that have an electron mobility of 10⁻⁶ cm²/Vs or more.

The electron-transport layer 114 is not limited to a single layer, and may be a stack including two or more layers containing any of the above substances.

Between the electron-transport layer and the light-emitting layer, a layer that controls transport of electron carriers may be provided. This is a layer formed by addition of a small amount of a substance having a high electron-trapping property to the above materials having a high electron-transport property, and the layer is capable of adjusting carrier balance by retarding transport of electron carriers. Such a structure is very effective in preventing a problem (such as a reduction in element lifetime) caused when electrons pass through the light-emitting layer.

In addition, the electron-injection layer 115 may be provided in contact with the second electrode 102 between the electron-transport layer 114 and the second electrode 102. For the electron-injection layer 115, an alkali metal, an alkaline earth metal, or a compound thereof, such as lithium fluoride (LiF), cesium fluoride (CsF), or calcium fluoride (CaF₂), can be used. For example, a layer that is formed using a substance having an electron-transport property and contains an alkali metal, an alkaline earth metal, or a compound thereof can be used. In addition, an electride may be used for the electron-injection layer 115. Examples of the electride include a substance in which electrons are added at high concentration to calcium oxide-aluminum oxide. Note that a layer that is formed using a substance having an electron-transport property and contains an alkali metal or an alkaline earth metal is preferably used as the electron-injection layer 115, in which case electron injection from the second electrode 102 is efficiently performed.

Instead of the electron-injection layer 115, a charge-generation layer 116 may be provided (FIG. 1B). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the second electrode 102 serving as a cathode; thus, the light-emitting element operates. When a layer containing organic compounds of one embodiment of the present invention exists in the electron-transport layer 114 so as to be in contact with the charge-generation layer 116, a luminance decrease due to accumulation of driving time of the light-emitting element can be suppressed, and thus, the light-emitting element can have a long lifetime.

Note that the charge-generation layer 116 preferably includes either an electron-relay layer 118 or an electron-injection buffer layer 119 or both in addition to the p-type layer 117.

The electron-relay layer 118 contains at least the substance having an electron-transport property and has a function of preventing an interaction between the electron-injection buffer layer 119 and the p-type layer 117 and smoothly transferring electrons. The LUMO level of the substance having an electron-transport property contained in the electron-relay layer 118 is preferably between the LUMO level of the substance having an acceptor property in the p-type layer 117 and the LUMO level of a substance contained in a layer of the electron-transport layer 114 in contact with the charge-generation layer 116. As a specific value of the energy level, the LUMO level of the substance having an electron-transport property in the electron-relay layer 118 is preferably higher than or equal to −5.0 eV, more preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

A substance having a high electron-injection property can be used for the electron-injection buffer layer 119. For example, an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)) can be used.

In the case where the electron-injection buffer layer 119 contains the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound of the above metal (e.g., an alkali metal compound (including an oxide such as lithium oxide, a halide, and a carbonate such as lithium carbonate or cesium carbonate), an alkaline earth metal compound (including an oxide, a halide, and a carbonate), and a rare earth metal compound (including an oxide, a halide, and a carbonate)). Note that as the substance having an electron-transport property, a material similar to the above-described material used for the electron-transport layer 114 can be used. Furthermore, the organic compound of the present invention can be used.

For the second electrode 102, any of metals, alloys, electrically conductive compounds, and mixtures thereof which have a low work function (specifically, a work function of 3.8 eV or less) or the like can be used. Specific examples of such a cathode material are elements belonging to Groups 1 and 2 of the periodic table, such as alkali metals (e.g., lithium (Li) and cesium (Cs)), magnesium (Mg), calcium (Ca), and strontium (Sr), alloys thereof (e.g., MgAg and AlLi), rare earth metals such as europium (Eu) and ytterbium (Yb), alloys thereof, and the like. However, when the electron-injection layer is provided between the second electrode 102 and the electron-transport layer, for the second electrode 102, any of a variety of conductive materials such as Al, Ag, ITO, or indium oxide-tin oxide containing silicon or silicon oxide can be used regardless of the work function. Films of these conductive materials can be formed by a dry method such as a vacuum evaporation method or a sputtering method, an inkjet method, a spin coating method, or the like. In addition, the films of these conductive materials may be formed by a wet method using a sol-gel method, or by a wet method using paste of a metal material.

Furthermore, any of a variety of methods can be employed for forming the layer 103 containing organic compounds regardless of a dry process or a wet process. For example, a vacuum evaporation method, a gravure printing method, an offset printing method, a screen printing method, an inkjet method, a spin coating method, or the like may be used.

Further, the electrodes may be formed using a sol-gel method, or may also be formed using paste of a metal material. Alternatively, the electrodes may be formed by a dry process such as a sputtering method or a vacuum evaporation method.

Light emission from the light-emitting element is extracted out through one or both of the first electrode 101 and the second electrode 102. Therefore, one or both of the first electrode 101 and the second electrode 102 are formed as a light-transmitting electrode.

The structure of the layers provided between the first electrode 101 and the second electrode 102 is not limited to the above-described structure. Preferably, a light-emitting region where holes and electrons recombine is positioned away from the first electrode 101 and the second electrode 102 so that quenching due to the proximity of the light-emitting region and a metal used for electrodes and carrier-injection layers can be prevented.

Furthermore, in order that transfer of energy from an exciton generated in the light-emitting layer can be suppressed, preferably, the hole-transport layer and the electron-transport layer which are in contact with the light-emitting layer 113, particularly a carrier-transport layer in contact with a side closer to the recombination region in the light-emitting layer 113, are formed using a substance whose singlet excitation energy level and triplet excitation energy level are the same as or higher than those of the first organic compound and the second organic compound.

Next, a mode of a light-emitting element with a structure in which a plurality of light-emitting units are stacked (this type of light-emitting element is also referred to as a stacked element) is described with reference to FIG. 1C. This light-emitting element includes a plurality of light-emitting units between an anode and a cathode. One light-emitting unit has a structure similar to that of the layer 103 containing organic compounds, which is illustrated in FIG. 1A. In other words, the light-emitting element illustrated in FIG. 1A or 1B includes a single light-emitting unit, and the light-emitting element illustrated in FIG. 1C includes a plurality of light-emitting units.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied between the first electrode 501 and the second electrode 502. That is, in FIG. 1C, the charge-generation layer 513 injects electrons into the first light-emitting unit 511 and holes into the second light-emitting unit 512 when a voltage is applied so that the potential of the first electrode becomes higher than the potential of the second electrode.

The charge-generation layer 513 preferably has a structure similar to the structure of the charge-generation layer 116 described with reference to FIG. 1B. Since the composite material of an organic compound and a metal oxide is superior in carrier-injection property and carrier-transport property, low-voltage driving or low-current driving can be achieved. Note that when a surface of a light-emitting unit on the anode side is in contact with the charge-generation layer 513, the charge-generation layer 513 can also serve as a hole-injection layer of the light-emitting unit; thus, a hole-transport layer is not necessarily formed in the light-emitting unit.

In the case where the electron-injection buffer layer 119 is provided, the electron-injection buffer layer serves as the electron-injection layer in the light-emitting unit on the anode side and the light-emitting unit does not necessarily further need an electron-injection layer.

The light-emitting element having two light-emitting units is described with reference to FIG. 1C; however, the present invention can be similarly applied to a light-emitting element in which three or more light-emitting units are stacked. With a plurality of light-emitting units partitioned by the charge-generation layer 513 between a pair of electrodes as in the light-emitting element according to this embodiment, it is possible to provide an element which can emit light with high luminance with the current density kept low and has a long lifetime. A light-emitting device that can be driven at a low voltage and has low power consumption can be realized.

Furthermore, when emission colors of the light-emitting units are made different, light emission of a desired color can be obtained from the light-emitting element as a whole. For example, it is easy to enable a light-emitting element having two light-emitting units to emit white light as the whole element when the emission colors of the first light-emitting unit are red and green and the emission color of the second light-emitting unit is blue.

### <<Micro Optical Resonator (Microcavity) Structure>>

A light-emitting element with a microcavity structure is formed with the use of a reflective electrode and a semi-transmissive and semi-reflective electrode as the pair of electrodes. The reflective electrode and the semi-transmissive and semi-reflective electrode correspond to the first electrode and the second electrode described above. The light-emitting element with a microcavity structure includes at least a layer containing organic compounds between the reflective electrode and the semi-transmissive and semi-reflective electrode. The layer containing organic compounds includes at least a light-emitting layer serving as a light-emitting region.

Light emitted from the light-emitting layer included in the layer containing organic compounds is reflected and resonated by the reflective electrode and the semi-transmissive and semi-reflective electrode. Note that the reflective electrode has a visible light reflectivity of 40% to 100%, preferably 70% to 100%, and a resistivity of 1×10⁻² Ωcm or lower. In addition, the semi-transmissive and semi-reflective electrode has a visible light reflectivity of 20% to 80%, preferably 40% to 70%, and a resistivity of 1×10⁻² Ωcm or lower.

In the light-emitting element, by changing thicknesses of the transparent conductive film, the composite material, the carrier-transport material, and the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is emitted from the light-emitting layer and reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of color to be amplified). In that case, the phases of the first reflected light and the first incident light can be aligned with each other and the light emitted from the light-emitting layer can be further amplified.

Note that in the above structure, the layer containing organic compounds may include a plurality of light-emitting layers or may include a single light-emitting layer. The tandem type light-emitting element described above may be combined with the a plurality of layers containing organic compounds; for example, a light-emitting element may have a structure in which a plurality of layers containing organic compounds is provided, a charge-generation layer is provided between the layers containing the organic compounds, and each layer containing organic compounds is formed of a plurality of light-emitting layers or a single light-emitting layer.

### <<Light-Emitting Device>>

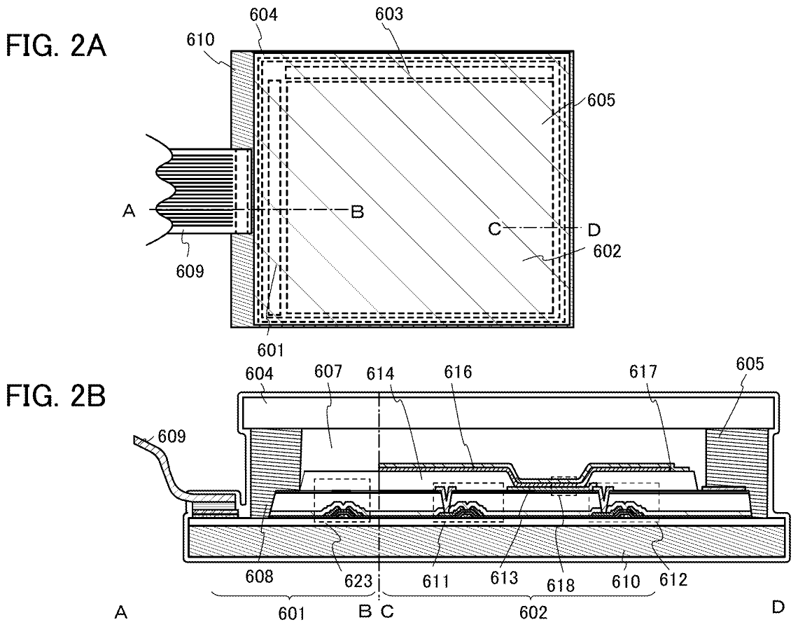

A light-emitting device of one embodiment of the present invention is described using FIGS. 2A and 2B. Note that FIG. 2A is a top view illustrating the light-emitting device and FIG. 2B is a cross-sectional view of FIG. 2A taken along lines A-B and C-D. This light-emitting device includes a driver circuit portion (source line driver circuit) 601, a pixel portion 602, and a driver circuit portion (gate line driver circuit) 603, which can control light emission of a light-emitting element and illustrated with dotted lines. A reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

Next, a cross-sectional structure will be described with reference to FIG. 2B. The driver circuit portion and the pixel portion are formed over an element substrate 610; the source line driver circuit 601, which is a driver circuit portion, and one of the pixels in the pixel portion 602 are illustrated here.

As the source line driver circuit 601, a CMOS circuit in which an n-channel FET 623 and a p-channel FET are combined is formed. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612. One embodiment of the present invention is not limited to the structure. The pixel portion may include three or more FETs and a capacitor in combination.

The kind and crystallinity of a semiconductor used for the FETs is not particularly limited; an amorphous semiconductor or a crystalline semiconductor may be used. Examples of the semiconductor used for the FETs include Group 13 semiconductors, Group 14 semiconductors, compound semiconductors, oxide semiconductors, and organic semiconductor materials. Oxide semiconductors are particularly preferable. Examples of the oxide semiconductor include an In—Ga oxide and an In-M-Zn oxide (M is Al, Ga, Y, Zr, La, Ce, or Nd). Note that an oxide semiconductor material that has an energy gap of 2 eV or more, preferably 2.5 eV or more, further preferably 3 eV or more is preferably used, in which case the off-state current of the transistors can be reduced.

Note that to cover an end portion of the first electrode 613, an insulator 614 is formed. The insulator 614 can be formed using a positive photosensitive acrylic resin film here.

The insulator 614 is formed to have a curved surface with curvature at its upper or lower end portion in order to obtain favorable coverage. For example, in the case where positive photosensitive acrylic is used for a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

A layer 616 containing organic compounds and a second electrode 617 are formed over the first electrode 613. The first electrode 613, the layer 616 containing organic compounds, and the second electrode 617 correspond, respectively, to the first electrode 101, the layer 103 containing organic compounds, and the second electrode 102 in FIG. 1A or to the first electrode 501, a layer 503 containing organic compounds, and the second electrode 502 in FIG. 1C. The layer 616 containing organic compounds preferably has a structure described in Embodiment 1.

The sealing substrate 604 is attached to the element substrate 610 with the sealing material 605, so that a light-emitting element 618 is provided in the space 607 surrounded by the element substrate 610, the sealing substrate 604, and the sealing material 605. The space 607 is filled with a filler, and may be filled with an inert gas (such as nitrogen or argon) or the sealing material 605. It is preferable that the sealing substrate 604 be provided with a recessed portion and a drying agent be provided in the recessed portion, in which case deterioration due to influence of moisture can be suppressed.

An epoxy-based resin or glass frit is preferably used for the sealing material 605. It is preferable that such a material do not transmit moisture or oxygen as much as possible. As the element substrate 610 and the sealing substrate 604, a glass substrate, a quartz substrate, or a plastic substrate formed of fiber reinforced plastic (FRP), polyvinyl fluoride (PVF), polyester, or acrylic can be used.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of materials of a flexible substrate, an attachment film, and a base material film include polyethylene terephthalate (PET), polyethylene naphthalate (PEN), polyether sulfone (PES), and polytetrafluoroethylene (PTFE), polypropylene, polyester, polyvinyl fluoride, polyvinyl chloride, polyamide, polyimide, aramid, epoxy, an inorganic vapor deposition film, and paper. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate, and the transistor or the light-emitting element may be provided directly on the flexible substrate. Still alternatively, a separation layer may be provided between the substrate and the transistor or the substrate and the light-emitting element. The separation layer can be used when part or the whole of a semiconductor device formed over the separation layer is separated from the substrate and transferred onto another substrate. In such a case, the transistor can be transferred to a substrate having low heat resistance or a flexible substrate. For the separation layer, a stack including inorganic films, which are a tungsten film and a silicon oxide film, or an organic resin film of polyimide or the like formed over a substrate can be used, for example.

In other words, a transistor or a light-emitting element may be formed using one substrate, and then transferred to another substrate. Examples of a substrate to which a transistor or a light-emitting element is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent characteristics or a transistor with low power consumption can be formed, a device with high durability or high heat resistance can be provided, or reduction in weight or thickness can be achieved.

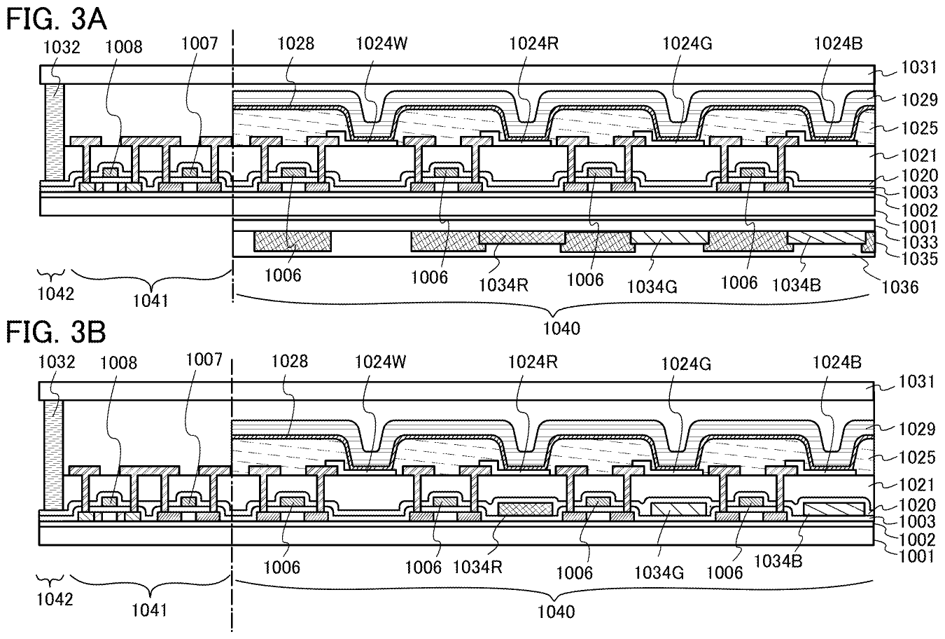

FIGS. 3A and 3B each illustrate an example of a light-emitting device in which full color display is achieved by formation of a light-emitting element exhibiting white light emission and with the use of coloring layers (color filters) and the like. In FIG. 3A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition 1025, a layer 1028 containing organic compounds, a second electrode 1029 of the light-emitting elements, a sealing substrate 1031, a sealing material 1032, and the like are illustrated.

In FIG. 3A, coloring layers (a red coloring layer 1034R, a green coloring layer 1034G, and a blue coloring layer 1034B) are provided on a transparent base material 1033. A black layer (a black matrix) 1035 may be additionally provided. The transparent base material 1033 provided with the coloring layers and the black layer is positioned and fixed to the substrate 1001. Note that the coloring layers and the black layer are covered with an overcoat layer 1036. In FIG. 3A, light emitted from part of the light-emitting layer does not pass through the coloring layers, while light emitted from the other part of the light-emitting layer passes through the coloring layers. Since light which does not pass through the coloring layers is white and light which passes through any one of the coloring layers is red, blue, or green, an image can be displayed using pixels of the four colors.

Since a light-emitting element of one embodiment of the present invention can have high emission efficiency and low power consumption, a light-emitting device including the light-emitting element can have low power consumption. Furthermore, an inexpensive light-emitting device which can be supplied stably can be provided, as compared to a light-emitting device in which a phosphorescent substance is used.

FIG. 3B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

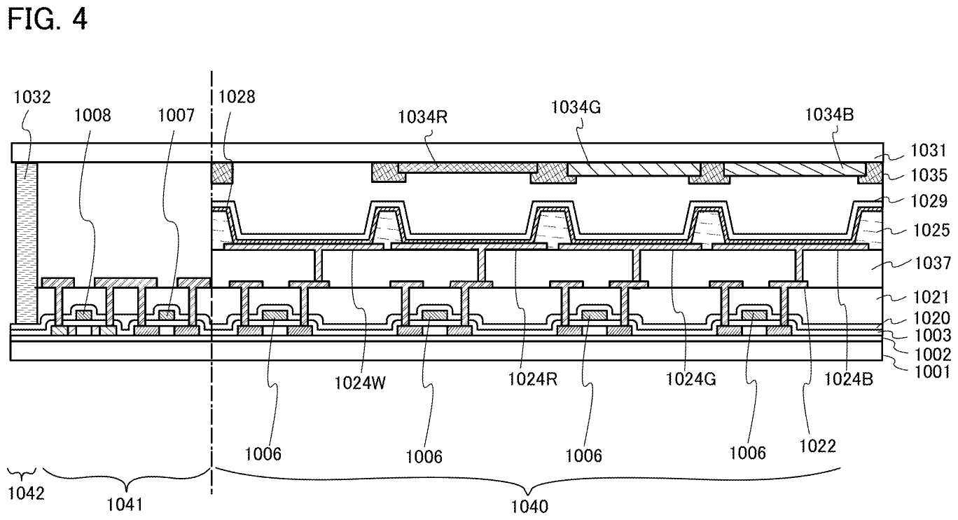

The above-described light-emitting device is a light-emitting device having a structure in which light is extracted from the substrate 1001 side where the FETs are formed (a bottom emission structure), but may be a light-emitting device having a structure in which light is extracted from the sealing substrate 1031 side (a top emission structure). FIG. 4 is a cross-sectional view of a light-emitting device having a top emission structure. In this case, a substrate which does not transmit light can be used as the substrate 1001. The process up to the step of forming a connection electrode which connects the FET and the anode of the light-emitting element is performed in a manner similar to that of the light-emitting device having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other various materials.

The first electrodes 1024W, 1024R, 1024G, and 1024B of the light-emitting elements each serve as an anode here, but may serve as a cathode. Further, in the case of a light-emitting device having a top emission structure as illustrated in FIG. 4, the first electrodes are preferably reflective electrodes. A layer 1028 containing organic compounds is formed to have a structure similar to the structures of the layer 103 containing organic compounds in FIG. 1A or the layer 503 containing organic compounds in FIG. 1B, with which white light emission can be obtained.

In the case of a top emission structure as illustrated in FIG. 4, sealing can be performed with the sealing substrate 1031 on which the coloring layers (the red coloring layer 1034R, the green coloring layer 1034G, and the blue coloring layer 1034B) are provided. The black layer (black matrix) 1035 may be provided on the sealing substrate 1031 so as to be located between the pixels. The coloring layers (the red coloring layer 1034R, the green coloring layer 1034G, and the blue coloring layer 1034B) and the black layer may be covered with the overcoat layer. Note that a light-transmitting substrate is used as the sealing substrate 1031.

Although an example in which full color display is performed using four colors of red, green, blue, and white is shown here, there is no particular limitation and full color display using three colors of red, green, and blue or four colors of red, green, blue, and yellow may be performed.

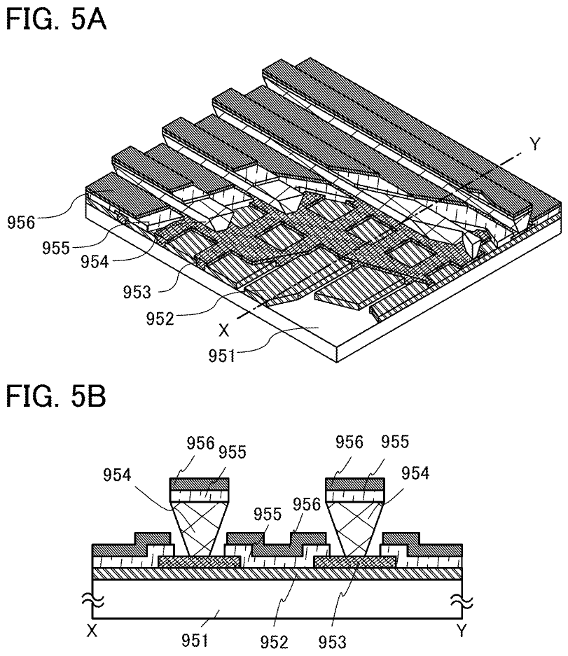

FIGS. 5A and 5B illustrate a passive matrix light-emitting device which is one embodiment of the present invention. FIG. 5A is a perspective view of the light-emitting device, and FIG. 5B is a cross-sectional view taken along a line X-Y of FIG. 5A. In FIGS. 5A and 5B, over a substrate 951, a layer 955 containing organic compounds is provided between an electrode 952 and an electrode 956. End portions of the electrode 952 are covered by an insulating layer 953. In addition, a partition layer 954 is provided over the insulating layer 953. A side wall of the partition layer 954 slopes so that a distance between one side wall and the other side wall becomes narrow toward a substrate surface. In other words, a cross section in the minor axis of the partition layer 954 is a trapezoidal shape of which the lower base (the side which is in the same direction as the plane direction of the insulating layer 953 and in contact with the insulating layer 953) is shorter than the upper base (the side which is in the same direction as the plane direction of the insulating layer 953 and not in contact with the insulating layer 953). The provision of the partition layer 954 in this manner can prevent the light-emitting element from being defective due to static electricity or the like.

Since many minute light-emitting elements arranged in a matrix can each be controlled with the FETs formed in the pixel portion, the above-described light-emitting device can be suitably used as a display device for displaying images.

### <<Lighting Device>>

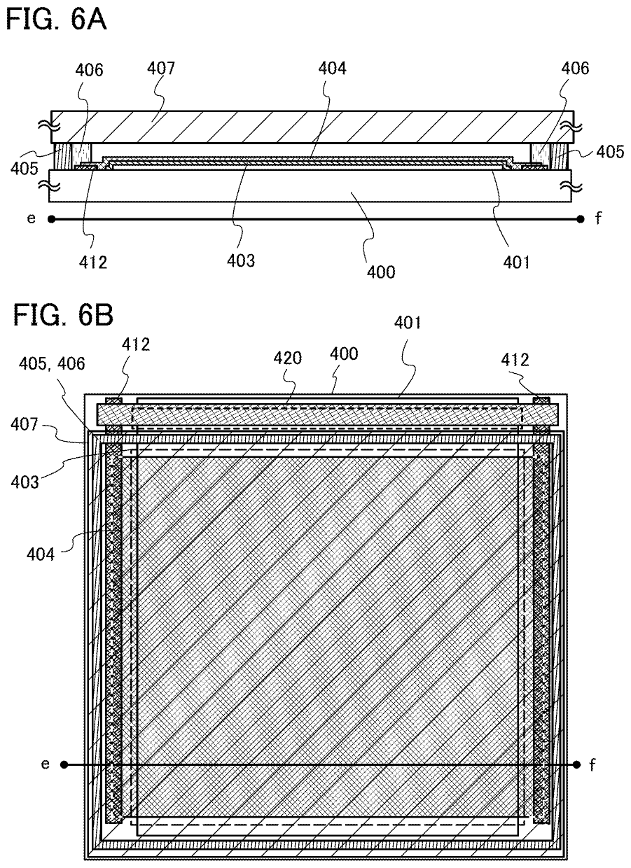

A lighting device which is one embodiment of the present invention is described with reference to FIGS. 6A and 6B. FIG. 6B is a top view of the lighting device, and FIG. 6A is a cross-sectional view of FIG. 6B taken along line e-f.

In the lighting device, a first electrode 401 is formed over a substrate 400 which is a support and has a light-transmitting property. The first electrode 401 corresponds to the first electrode 101 in FIGS. 1A and 1B. When light is extracted through the first electrode 401 side, the first electrode 401 is formed using a material having a light-transmitting property.

A pad 412 for applying a voltage to a second electrode 404 is provided over the substrate 400.

A layer 403 containing organic compounds is formed over the first electrode 401. The layer 403 containing organic compounds corresponds to, for example, the layer 103 containing organic compounds in FIG. 1A or the layer 503 containing organic compounds in FIG. 1C. For these structures, the description in Embodiment 1 can be referred to.

The second electrode 404 is formed to cover the layer 403 containing organic compounds. The second electrode 404 corresponds to the second electrode 102 in FIG. 1A. The second electrode 404 contains a material having high reflectivity when light is extracted through the first electrode 401 side. The second electrode 404 is connected to the pad 412, whereby voltage is applied thereto.

A light-emitting element is formed with the first electrode 401, the layer 403 containing organic compounds, and the second electrode 404. The light-emitting element is fixed to a sealing substrate 407 with sealing materials 405 and 406 and sealing is performed, whereby the lighting device is completed. It is possible to use only either the sealing material 405 or the sealing material 406. In addition, the inner sealing material 406 (not shown in FIG. 6B) can be mixed with a desiccant which enables moisture to be adsorbed, increasing reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

### <<Electronic Device>>

Examples of an electronic device which is one embodiment of the present invention are described. Examples of the electronic device are television devices (also referred to as TV or television receivers), monitors for computers and the like, cameras such as digital cameras and digital video cameras, digital photo frames, mobile phones (also referred to as cell phones or mobile phone devices), portable game machines, portable information terminals, audio playback devices, and large game machines such as pachinko machines. Specific examples of these electronic devices are given below.

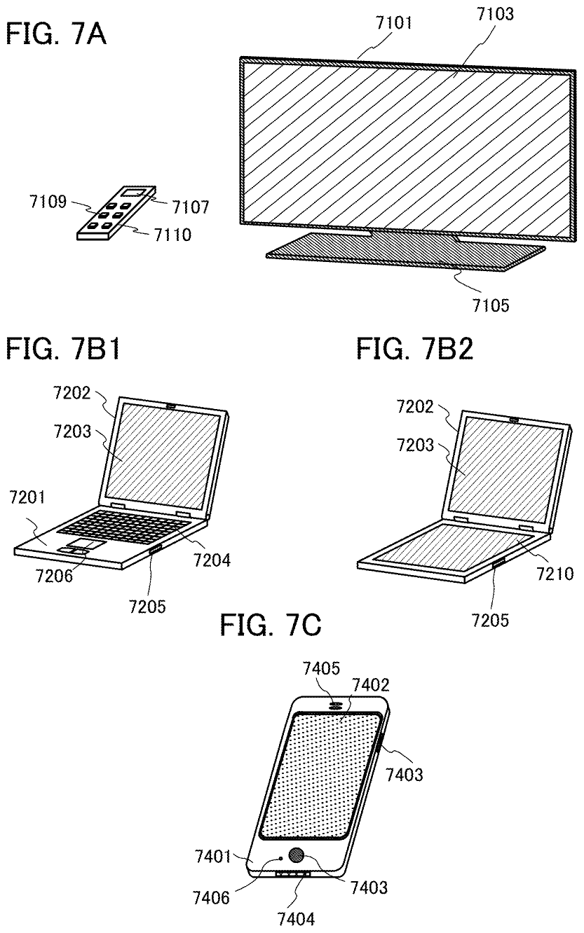

FIG. 7A illustrates an example of a television device. In the television device, a display portion 7103 is incorporated in a housing 7101. In addition, here, the housing 7101 is supported by a stand 7105. Images can be displayed on the display portion 7103, and in the display portion 7103, light-emitting elements are arranged in a matrix.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 7B1 illustrates a computer, which includes a main body 7201, a housing 7202, a display portion 7203, a keyboard 7204, an external connection port 7205, a pointing device 7206, and the like. Note that this computer is manufactured by using light-emitting elements arranged in a matrix in the display portion 7203. The computer illustrated in FIG. 7B1 may have a structure illustrated in FIG. 7B2. A computer illustrated in FIG. 7B2 is provided with a second display portion 7210 instead of the keyboard 7204 and the pointing device 7206. The second display portion 7210 is a touchscreen, and input can be performed by operation of display for input on the second display portion 7210 with a finger or a dedicated pen. The second display portion 7210 can also display images other than the display for input. The display portion 7203 may also be a touchscreen. Connecting the two screens with a hinge can prevent troubles; for example, the screens can be prevented from being cracked or broken while the computer is being stored or carried.

FIG. 7C illustrates an example of a portable information terminal. The portable information terminal is provided with a display portion 7402 incorporated in a housing 7401, operation buttons 7403, an external connection port 7404, a speaker 7405, a microphone 7406, and the like. Note that the portable information terminal has the display portion 7402 including light-emitting elements arranged in a matrix.

Information can be input to the portable information terminal illustrated in FIG. 7C by touching the display portion 7402 with a finger or the like. In this case, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a text input mode mainly for inputting text is selected for the display portion 7402 so that text displayed on a screen can be input. In this case, it is preferable to display a keyboard or number buttons on almost the entire screen of the display portion 7402.

When a detection device including a sensor such as a gyroscope or an acceleration sensor for sensing inclination is provided inside the mobile phone, screen display of the display portion 7402 can be automatically changed by determining the orientation of the mobile phone (whether the mobile phone is placed horizontally or vertically).

The screen modes are switched by touch on the display portion 7402 or operation with the operation buttons 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal detected by an optical sensor in the display portion 7402 is detected, the screen mode may be controlled so as to be switched from the input mode to the display mode.

The display portion 7402 may function as an image sensor. For example, an image of a palm print, a fingerprint, or the like is taken by the display portion 7402 while in touch with the palm or the finger, whereby personal authentication can be performed. Furthermore, by providing a backlight or a sensing light source which emits near-infrared light in the display portion, an image of a finger vein, a palm vein, or the like can be taken.

Note that in the above electronic devices, any of the structures described in this specification can be combined as appropriate.

The display portion preferably includes a light-emitting element of one embodiment of the present invention. The light-emitting element can have high emission efficiency. Further, the light-emitting elements can be driven at a low voltage. Thus, the electronic device including the light-emitting element of one embodiment of the present invention can have low power consumption.

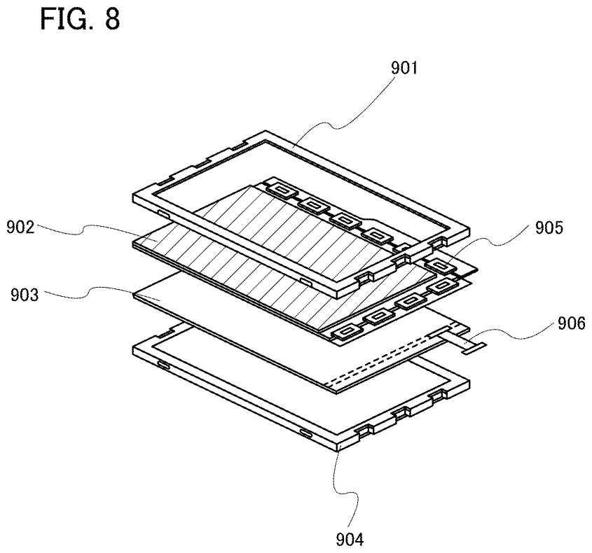

FIG. 8 illustrates an example of a liquid crystal display device including the light-emitting element for a backlight. The liquid crystal display device illustrated in FIG. 8 includes a housing 901, a liquid crystal layer 902, a backlight unit 903, and a housing 904. The liquid crystal layer 902 is connected to a driver IC 905. The light-emitting element is used for the backlight unit 903, to which current is supplied through a terminal 906.

As the light-emitting element, a light-emitting element of one embodiment of the present invention is preferably used. By including the light-emitting element, the backlight of the liquid crystal display device can have low power consumption.

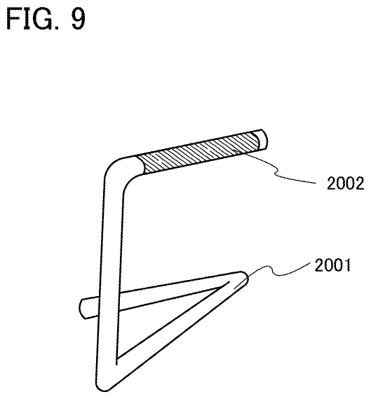

FIG. 9 illustrates an example of a desk lamp which is one embodiment of the present invention. The desk lamp illustrated in FIG. 9 includes a housing 2001 and a light source 2002, and a lighting device including a light-emitting element is used as the light source 2002.

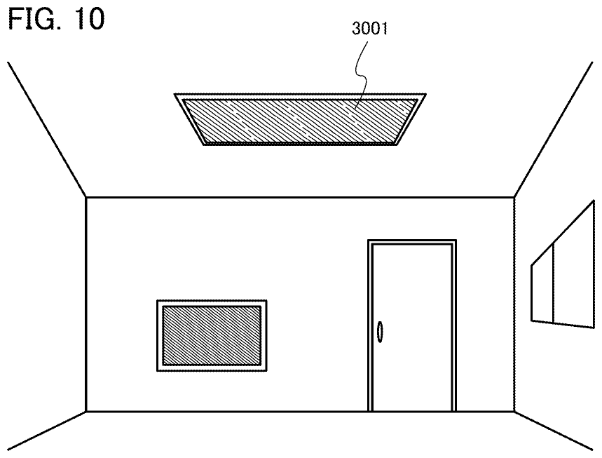

FIG. 10 illustrates an example of an indoor lighting device 3001. The light-emitting element of one embodiment of the present invention is preferably used in the lighting device 3001.

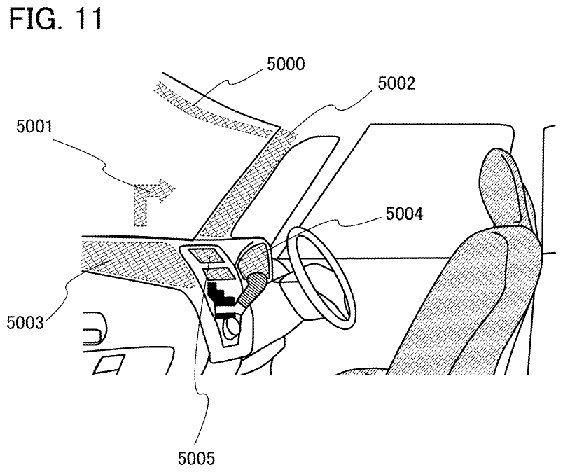

An automobile which is one embodiment of the present invention is illustrated in FIG. 11. In the automobile, light-emitting elements are used for a windshield and a dashboard. Display regions 5000 to 5005 are provided by using the light-emitting elements. The automobile preferably includes the light-emitting elements of one embodiment of the present invention, in which case the light-emitting elements can have low power consumption. This also suppresses power consumption of the display regions 5000 to 5005, showing suitability for use in an automobile.

The display regions 5000 and 5001 are display devices which are provided in the automobile windshield and which include the light-emitting elements. When a first electrode and a second electrode are formed of electrodes having light-transmitting properties in these light-emitting elements, what is called a see-through display device, through which the opposite side can be seen, can be obtained. Such a see-through display device can be provided even in the automobile windshield, without hindering the vision. Note that in the case where a transistor for driving or the like is provided, a transistor having a light-transmitting property, such as an organic transistor using an organic semiconductor material or a transistor using an oxide semiconductor, is preferably used.

The display region 5002 is a display device which is provided in a pillar portion and which includes the light-emitting element. The display region 5002 can compensate for the view hindered by the pillar portion by showing an image taken by an imaging unit provided in the car body. Similarly, a display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation information, a speedometer, a tachometer, a mileage, a fuel meter, a gearshift indicator, and air-condition setting. The content or layout of the display can be changed freely by a user as appropriate. Note that such information can also be shown by the display regions 5000 to 5003. The display regions 5000 to 5005 can also be used as lighting devices.

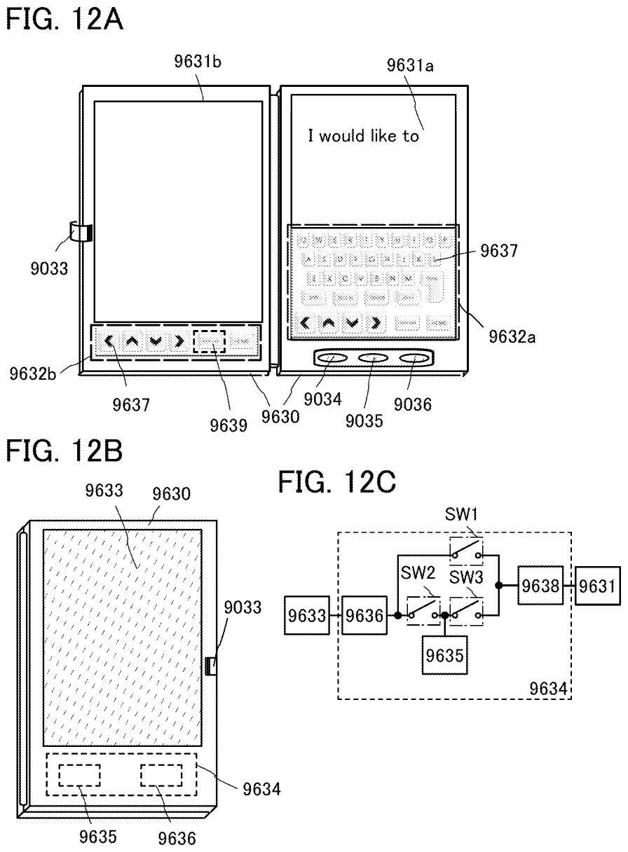

FIGS. 12A and 12B illustrate an example of a foldable tablet terminal. FIG. 12A illustrates the tablet terminal which is unfolded. The tablet terminal includes a housing 9630, a display portion 9631a, a display portion 9631b, a display mode switch 9034, a power switch 9035, a power-saving mode switch 9036, and a clip 9033. Note that in the tablet terminal, one or both of the display portion 9631a and the display portion 9631b is/are formed using a light-emitting device which includes the light-emitting element of one embodiment of the present invention.

Part of the display portion 9631a can be a touchscreen region 9632a and data can be input when a displayed operation key 9637 is touched. Although half of the display portion 9631a has only a display function and the other half has a touchscreen function, one embodiment of the present invention is not limited to the structure. The whole display portion 9631a may have a touchscreen function. For example, a keyboard can be displayed on the entire region of the display portion 9631a so that the display portion 9631a is used as a touchscreen, and the display portion 9631b can be used as a display screen.

Like the display portion 9631a, part of the display portion 9631b can be a touchscreen region 9632b. When a switching button 9639 for showing/hiding a keyboard on the touchscreen is touched with a finger, a stylus, or the like, the keyboard can be displayed on the display portion 9631b.

Touch input can be performed in the touchscreen region 9632a and the touchscreen region 9632b at the same time.

The display mode switch 9034 can switch the display between portrait mode, landscape mode, and the like, and between monochrome display and color display, for example. The power-saving mode switch 9036 can control display luminance in accordance with the amount of external light in use of the tablet terminal sensed by an optical sensor incorporated in the tablet terminal. Another sensing device including a sensor such as a gyroscope or an acceleration sensor for sensing inclination may be incorporated in the tablet terminal, in addition to the optical sensor.

Although FIG. 12A illustrates an example in which the display portion 9631a and the display portion 9631b have the same display area, one embodiment of the present invention is not limited to the example. The display portion 9631a and the display portion 9631b may have different display areas and different display quality. For example, higher resolution images may be displayed on one of the display portions 9631a and 9631b.

FIG. 12B illustrates the tablet terminal which is folded. The tablet terminal in this embodiment includes the housing 9630, a solar cell 9633, a charge and discharge control circuit 9634, a battery 9635, and a DCDC converter 9636. In FIG. 12B, a structure including the battery 9635 and the DCDC converter 9636 is illustrated as an example of the charge and discharge control circuit 9634.

Since the tablet terminal is foldable, the housing 9630 can be closed when the tablet terminal is not in use. As a result, the display portion 9631a and the display portion 9631b can be protected, thereby providing a tablet terminal with high endurance and high reliability for long-term use.

The tablet terminal illustrated in FIGS. 12A and 12B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar cell 9633 provided on a surface of the tablet terminal can supply power to the touchscreen, the display portion, a video signal processing portion, or the like. Note that a structure in which the solar cell 9633 is provided on one or both surfaces of the housing 9630 is preferable because the battery 9635 can be charged efficiently.

The structure and operation of the charge and discharge control circuit 9634 illustrated in FIG. 12B are described with reference to a block diagram of FIG. 12C. FIG. 12C illustrates the solar cell 9633, the battery 9635, the DCDC converter 9636, a converter 9638, switches SW1 to SW3, and a display portion 9631. The battery 9635, the DCDC converter 9636, the converter 9638, and the switches SW1 to SW3 correspond to the charge and discharge control circuit 9634 illustrated in FIG. 12B.

First, description is made on an example of the operation in the case where power is generated by the solar cell 9633 with the use of external light. The voltage of the power generated by the solar cell is raised or lowered by the DCDC converter 9636 so as to be voltage for charging the battery 9635. Then, when power from the solar cell 9633 is used for the operation of the display portion 9631, the switch SW1 is turned on and the voltage of the power is raised or lowered by the converter 9638 so as to be voltage needed for the display portion 9631. When images are not displayed on the display portion 9631, the switch SW1 is turned off and the switch SW2 is turned on so that the battery 9635 is charged.

Although the solar cell 9633 is described as an example of a power generation unit, the power generation unit is not particularly limited, and the battery 9635 may be charged by another power generation unit such as a piezoelectric element or a thermoelectric conversion element (Peltier element). The battery 9635 may be charged by a non-contact power transmission module capable of performing charging by transmitting and receiving power wirelessly (without contact), or another charge unit used in combination, and the power generation unit is not necessarily provided.

One embodiment of the present invention is not limited to the tablet terminal having the shape illustrated in FIGS. 12A to 12C as long as the display portion 9631 is included.

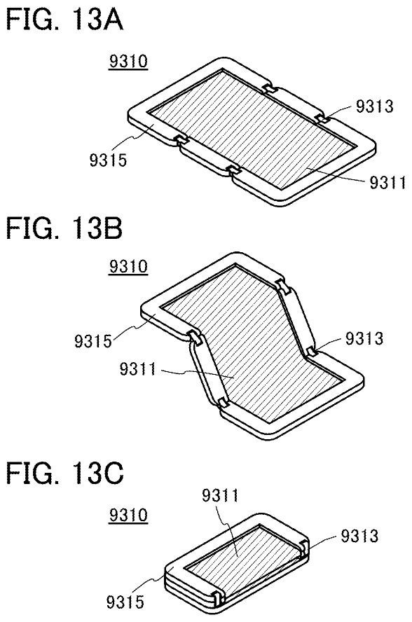

FIGS. 13A to 13C illustrate a foldable portable information terminal 9310. FIG. 13A illustrates the portable information terminal 9310 that is opened. FIG. 13B illustrates the portable information terminal 9310 that is being opened or being folded. FIG. 13C illustrates the portable information terminal 9310 that is folded. The portable information terminal 9310 is highly portable when folded. When the portable information terminal 9310 is opened, a seamless large display region is highly browsable.

A display panel 9311 is supported by three housings 9315 joined together by hinges 9313. Note that the display panel 9311 may be a touch panel (an input/output device) including a touch sensor (an input device). By bending the display panel 9311 at a connection portion between two housings 9315 with the use of the hinges 9313, the portable information terminal 9310 can be reversibly changed in shape from an opened state to a folded state. The light-emitting device of one embodiment of the present invention can be used for the display panel 9311. A display region 9312 in the display panel 9311 is a display region that is positioned at the side surface of the portable information terminal 9310 that is folded. On the display region 9312, information icons, file shortcuts of frequently used applications or programs, and the like can be displayed, and confirmation of information and start of application can be smoothly performed.

### Example 1

In this example, light-emitting elements 1 to 4 which are the light-emitting elements of embodiments of the present invention described in Embodiment 1 of the present invention will be described. Structural formulae of organic compounds used for light-emitting elements 1 to 4 are shown below.

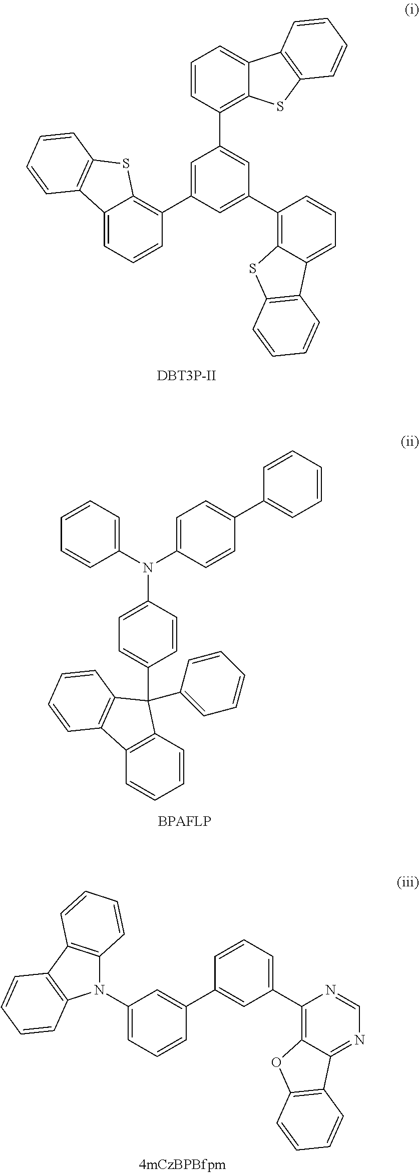

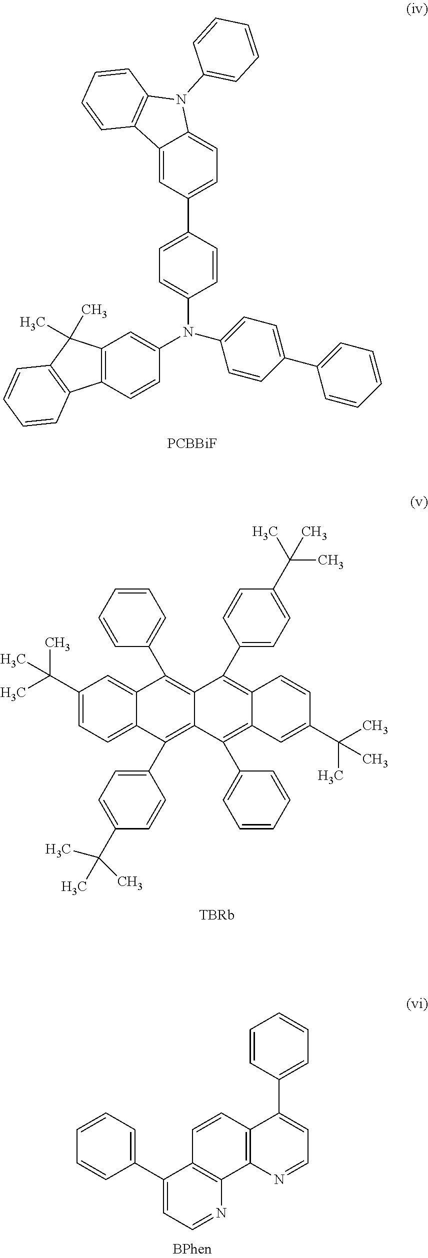

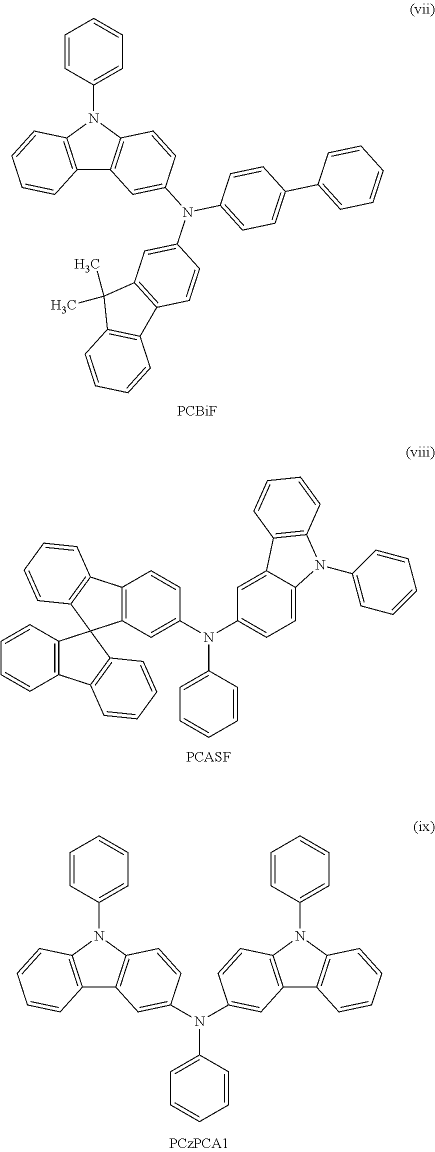

### (Method for Fabricating Light-Emitting Element 1)

First, silicon or indium tin oxide containing silicon oxide (ITSO) was formed on a glass substrate by a sputtering method to form the first electrode 101. It is to be noted that the film thickness of the first electrode was set to be 110 nm and that the area of the electrode was set to be 2 mm×2 mm.

Next, in pretreatment for forming the light-emitting element over the substrate, a surface of the substrate was washed with water and baked at 200° C. for one hour, and then UV ozone treatment was performed for 370 seconds.

After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate over which the first electrode 101 was formed was fixed to a substrate holder provided in the vacuum evaporation apparatus so that the surface on which the first electrode 101 was formed faced downward. The pressure in the vacuum evaporation apparatus was reduced to approximately 10⁻⁴ Pa. After that, on the first electrode 101, 4,4′,4″-(benzene-1,3,5-triyOtri(dibenzothiophene) (abbreviation: DBT3P-II) represented by Structural Formula (i) and molybdenum(VI) oxide were deposited by co-evaporation to a thickness of 60 nm at a weight ratio of 4:2 (=DBT3P-II: molybdenum oxide) by an evaporation method using resistance heating, so that the hole-injection layer 111 was formed.

Next, a film of 4-phenyl-4′-(9-phenylfluoren-9-yl)triphenylamine (abbreviation: BPAFLP) which is represented by Structural Formula (ii) was formed to a thickness of 20 nm over the hole-injection layer 111 to form the hole-transport layer 112.

Furthermore, on the hole-transport layer 112, 4-{3-[3′-(9H-carbazol-9-yl)]biphenyl-3-yl}benzofuro[3,2-d]pyrimidine (abbreviation: 4mCzBPBfpm) represented by the above structural formula (iii), N-(1,1′-biphenyl-4-yl)-9,9-dimethyl-N-[4-(9-phenyl-9H-carbazol-3-yl)phenyl]-9H-fluoren-2-amine (abbreviation: PCBBiF) represented by the above structural formula (iv) and 2,8-di-tert-butyl-5,11-bis(4-tert-butylphenyl)-6,12-diphenyltetracene (abbreviation: TBRb) were deposited by co-evaporation to a thickness of 40 nm at a weight ratio of 0.8:0.2:0.01 (=4mCzBPBfpm:PCBBiF: TBRb), so that the light-emitting layer 113 was formed.

Next, on the light-emitting layer 113, 4mCzBPBfpm was deposited to a thickness of 20 nm as the electron transport layer 114, and then, bathophenanthroline (abbreviation: BPhen) represented by the above structural formula (v) was deposited to a thickness of 10 nm as the electron-injection layer 115.

After the formation of the electron-transport layer 114 and the electron-injection layer 115, lithium fluoride (LiF) was deposited by evaporation to a thickness of 1 nm and aluminum was deposited by evaporation to a thickness of 200 nm to form the second electrode 102. Thus, the light-emitting element 1 in this example was fabricated.

### (Method for Fabricating Light-Emitting Element 2)

The light-emitting element 2 was fabricated in the same manner as the light-emitting element 1 except that PCBBiF in the light-emitting layer 113 of the light-emitting element 1 was replaced with N-(4-biphenyl)-N-(9,9-dimethyl-9H-fluoren-2-yl)-9-phenyl-9H-carbazol-3-amine (abbreviation: PCBiF) represented by the above structural formula (vii).

### (Method for Fabricating Light-Emitting Element 3)

The light-emitting element 3 was fabricated in the same manner as the light-emitting element 1 except that PCBBiF in the light-emitting layer 113 of the light-emitting element 1 was replaced with 2-[N-(9-phenylcarbazol-3-yl)-N-phenylamino]spiro-9,9′-bifluorene (abbreviation: PCASF) represented by the above structural formula (viii).

### (Method for Fabricating Light-Emitting Element 4)

The light-emitting element 4 was fabricated in the same manner as the light-emitting element 1 except that PCBBiF in the light-emitting layer 113 of the light-emitting element 1 was replaced with 3-[N-(9-phenylcarbazol-3-yl)-N-phenylamino]-9-phenylcarbazole (abbreviation: PCzPCA1) represented by the above structural formula (ix).

Table 1 shows the element structures of the light-emitting elements 1 to 4.

TABLE 1

| | Hole- | Hole- | Light- | Electron- | Electron- |
|---|---|---|---|---|---|
| | injection | transport | emitting | transport | injection |
| | layer | layer | layer | layer | layer |
| | 60 nm | 20 nm | 40 nm | 20 nm | 10 nm |
| Light-emitting element 1 | DBT3P-II: | BPAFLP | 4mCzBPBfpm: | 4mCzBPBfpm | BPhen |
| | MoOX | | PCBBiF: | | |
| | 4:2 | | TBRb | | |
| | | | (0.8:0.2:0.01) | | |
| Light-emitting element 2 | | | 4mCzBPBfpm: | | |
| | | | PCBiF: | | |
| | | | TBRb | | |
| | | | (0.8:0.2:0.01) | | |
| Light-emitting element 3 | | | 4mCzBPBfpm: | | |
| | | | PCASF: | | |
| | | | TBRb | | |
| | | | (0.8:0.2:0.01) | | |
| Light-emitting element 4 | | | 4mCzBPBfpm: | | |
| | | | PCzPCA1: | | |
| | | | TBRb | | |
| | | | (0.8:0.2:0.01) | | |

The light-emitting elements 1 to 4 were each sealed using a glass substrate in a glove box containing a nitrogen atmosphere so as not to be exposed to the air (specifically, a sealing material was applied onto an outer edge of the element, and at the time of sealing, first, UV treatment was performed and then heat treatment was performed at 80° C. for 1 hour). Then, initial characteristics of these light-emitting elements were measured. Note that the measurements were performed at room temperature (in an atmosphere kept at 25° C.).

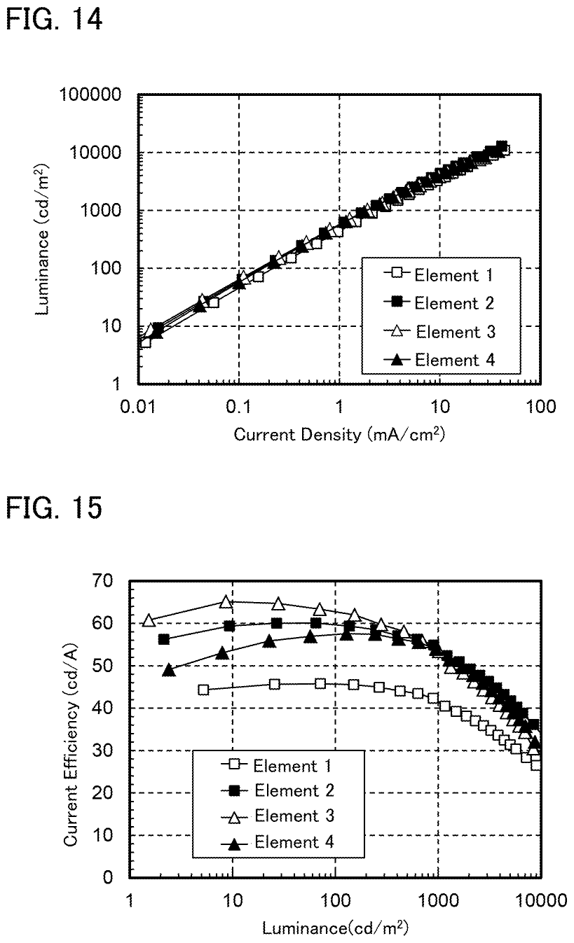

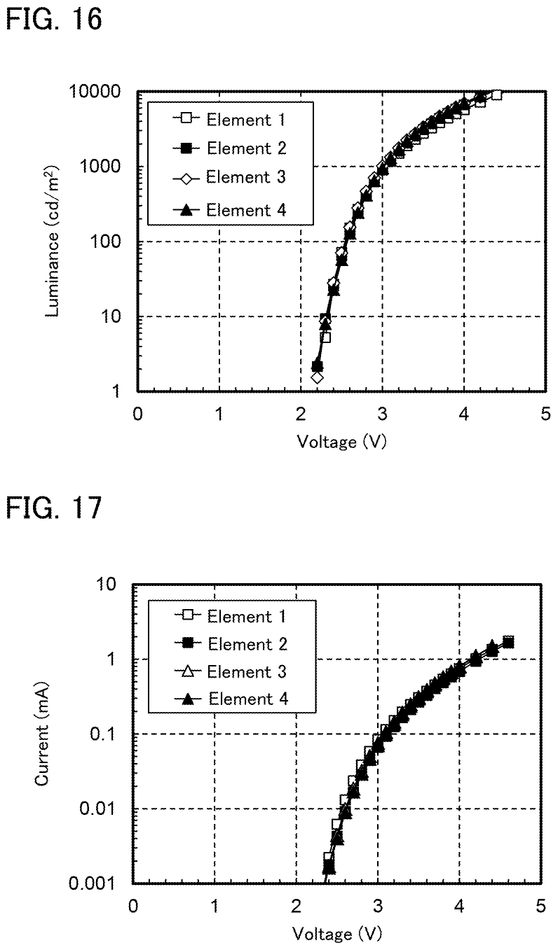

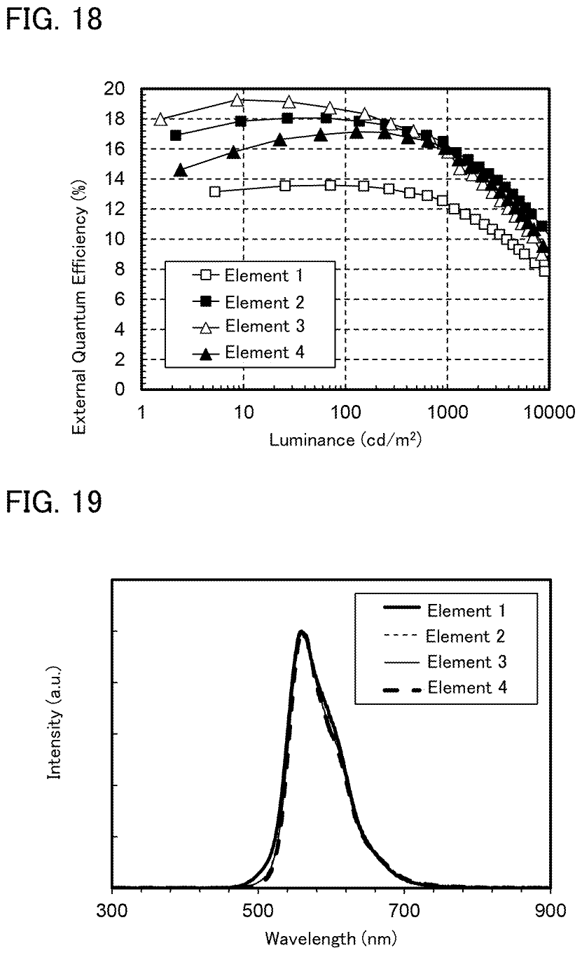

FIG. 14 shows the luminance-current density characteristics of the light-emitting elements 1 to 4. FIG. 15 shows current efficiency-luminance characteristics thereof. FIG. 16 shows luminance-voltage characteristics thereof. FIG. 17 shows current-voltage characteristics thereof. FIG. 18 shows external quantum efficiency-luminance characteristics thereof. FIG. 19 shows emission spectra thereof. Table 2 shows main characteristics of the light-emitting elements at approximately 1000 cd/m².

TABLE 2

| | | Current | | | Current | External | Maximum external |
|---|---|---|---|---|---|---|---|
| | Voltage | density | Chromaticity | Chromaticity | efficiency | quantum | quantum efficiency |
| | (V) | (mA/cm²) | x | y | (cd/A) | efficiency (%) | (%) |
| Light-emitting | 3.0 | 2.1 | 0.48 | 0.51 | 42 | 12.6 | 13.6 |
| element 1 | | | | | | | |
| Light-emitting | 3.0 | 1.7 | 0.49 | 0.51 | 55 | 16.5 | 18.1 |
| element 2 | | | | | | | |
| Light-emitting | 3.0 | 1.9 | 0.48 | 0.51 | 53 | 15.8 | 19.3 |
| element 3 | | | | | | | |
| Light-emitting | 3.0 | 1.8 | 0.49 | 0.51 | 54 | 16.1 | 17.1 |
| element 4 | | | | | | | |

It can be found from FIG. 14, FIG. 15, FIG. 16, FIG. 17, FIG. 18, FIG. 19, and Table 2 that each of the light-emitting elements is a light-emitting element with favorable characteristics. Each of the light-emitting elements exhibits an external quantum efficiency far exceeding a theoretical limit 7.5% of the fluorescent light-emitting element in the case where the outcoupling efficiency is 30%. In particular, the light-emitting element 3 exhibits the maximum excellent external quantum efficiency as high as 19.3%. Since these light-emitting elements 1 to 4 do not have a special structure for improvement of light extraction efficiency, the light extraction efficiency is estimated to be about 30% which is similar to the above assumption. The driving voltage of each of the light-emitting elements is 3.0 V, that is, the light-emitting elements can be driven at a very low voltage.

As described above, the light-emitting element of one embodiment of the present invention, in which an exciplex is used as an energy donor of fluorescent substance and one of two organic compounds that form the exciplex is a substance having a first skeleton including a benzofuropyrimidine skeleton or a benzothienopyrimidine skeleton, can have extremely high emission efficiency and can be driven at a low voltage.

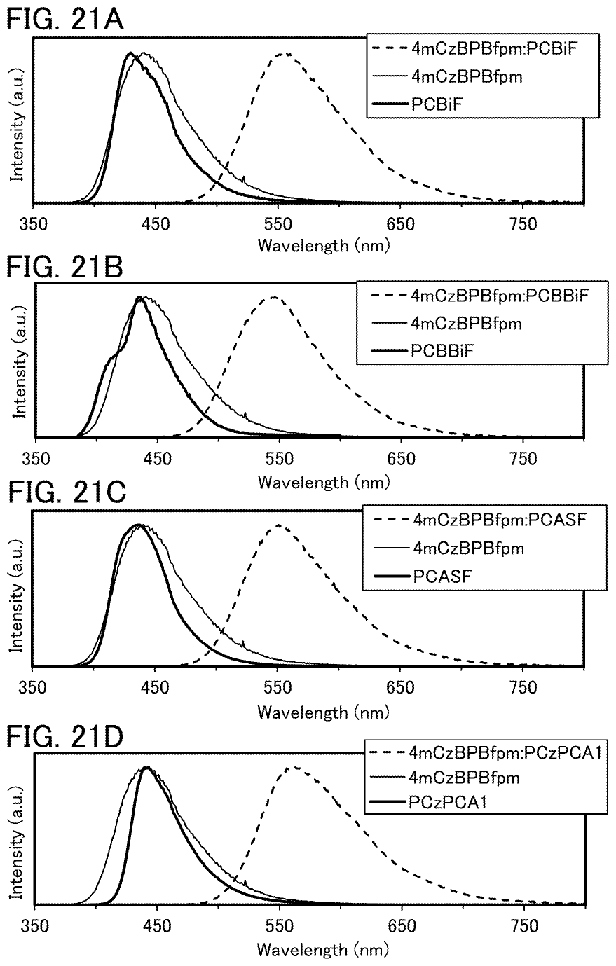

Here, the first organic compound and the second organic compound contained in a light-emitting layer of each element and the exciplex formed by the organic compounds are described with reference to FIGS. 21A to 21D. FIGS. 21A to 21D show photoluminescence (PL) spectra of thin films of the first organic compound and the second organic compound which are used for the light-emitting elements 1 to 4, and electroluminescence (EL) spectra of light emitting elements including a mixed film of the first organic compound and the second organic compound as a light-emitting layer.

FIG. 21A shows PL spectra of a 4mCzBPBfpm thin film and a PCBBiF thin film, and an EL spectrum of a light-emitting element A in which these thin films are used for a light-emitting layer. FIG. 21B shows PL spectra of a 4mCzBPBfpm thin film and a PCBBiF thin film, and an EL spectrum of a light-emitting element B in which these thin films are used for a light-emitting layer. FIG. 21C shows PL spectra of a 4mCzBPBfpm thin film and a PCBBiF thin film, and an EL spectrum of a light-emitting element C in which these thin films are used for a light-emitting layer. FIG. 21D shows PL spectra of a 4mCzBPBfpm thin film and a PCBBiF thin film, and an EL spectrum of a light-emitting element D in which these thin films are used for a light-emitting layer.

TBRb, a fluorescent substance used for the light-emitting elements 1 to 4, is not used in the light-emitting layers of the elements whose EL spectra are measured in each graph. The light-emitting element A, the light-emitting element B, the light-emitting element C, and the light-emitting element D, whose EL spectra are measured, correspond to the light-emitting element 1, the light-emitting element 2, the light-emitting element 3, and the light-emitting element 4, respectively. The element structures of the light-emitting elements A to D are the same as the structures without TBRb in the corresponding light-emitting elements.

The results indicate that the EL spectra of the elements in FIGS. 21A to 21D are positioned on a long wavelength side compared with each of the PL spectra of the first organic compound and the second organic compound.

Since the number of emission peaks of the each spectrum is one, the light emission is derived from a single state. For this reason, there is a high probability that the first organic compound and the second organic compound which are used in each of the light-emitting elements in this example form an exciplex.

In this manner, in the light-emitting elements 1 to 4 in this example, the first organic compound and the second organic compound form an exciplex in the light-emitting layer, and the energy is transferred from the exciplex to the fluorescent substance. Accordingly, the light-emitting elements 1 to 4 have extremely high emission efficiency.

Although there is a small difference in a peak position and a spectrum shape between PL spectra of the thin films and the EL spectrum of the element, the difference is not big enough to significantly affect the possibility that these organic compounds form an exciplex.

This application is based on Japanese Patent Application serial no. 2015-109818 filed with Japan Patent Office on May 29, 2015, the entire contents of which are hereby incorporated by reference.

1. (canceled)

2. A light-emitting device comprising:
a first electrode;
a light-emitting layer over the first electrode; and
a second electrode over the light-emitting layer,
wherein the light-emitting layer comprises a fluorescent substance, a first organic compound, and a second organic compound,
wherein the first organic compound and the second organic compound are configured to form an exciplex,
wherein the exciplex exhibits thermally activated delayed fluorescence,
wherein the first organic compound comprises a first skeleton that is a benzofuro[3,2-d]pyrimidine skeleton or a benzothieno[3,2-d]pyrimidine skeleton and a second skeleton that is a carbazole skeleton,
wherein the first skeleton and the second skeleton are connected via a linking group,
wherein a 4-position of the first skeleton is bonded to the linking group,
wherein a 2-position of the first skeleton is bonded to a hydrogen,
wherein the second organic compound includes a π-electron rich heteroaromatic ring skeleton or an aromatic amine skeleton,
wherein an energy difference between a singlet excitation energy level of the exciplex and a triplet excitation energy level of the exciplex is greater than or equal to 0 eV and less than or equal to 0.2 eV, and
wherein the triplet excitation energy level of the exciplex is higher than a triplet excitation energy level of the fluorescent substance.

3. A light-emitting device comprising:
a first electrode;
a light-emitting layer over the first electrode; and
a second electrode over the light-emitting layer,
wherein the light-emitting layer comprises a fluorescent substance, a first organic compound, and a second organic compound,
wherein the first organic compound and the second organic compound are configured to form an exciplex,
wherein the first organic compound comprises a first skeleton that is a benzofuro[3,2-d]pyrimidine skeleton or a benzothieno[3,2-d]pyrimidine skeleton and a second skeleton that is a carbazole skeleton,
wherein the first skeleton and the second skeleton are connected via a linking group,
wherein a 4-position of the first skeleton is bonded to the linking group,
wherein a 2-position of the first skeleton is bonded to a hydrogen,
wherein the second organic compound includes a π-electron rich heteroaromatic ring skeleton or an aromatic amine skeleton,
wherein an energy difference between a singlet excitation energy level of the exciplex and a triplet excitation energy level of the exciplex is greater than or equal to 0 eV and less than or equal to 0.2 eV,
wherein a triplet excitation energy of the exciplex is converted to a singlet excitation energy of the exciplex by reverse intersystem crossing, and
wherein the triplet excitation energy level of the exciplex is higher than a triplet excitation energy level of the fluorescent substance.

4. The light-emitting device according to claim 2, wherein a singlet excitation energy of the exciplex is transferred from the singlet excitation energy level of the exciplex to a singlet excitation energy level of the fluorescent substance.

5. The light-emitting device according to claim 4, wherein fluorescence is emitted from the singlet excitation energy level of the fluorescent substance.

6. The light-emitting device according to claim 2, wherein a 9-position of the carbazole skeleton is bonded to the linking group.

7. The light-emitting device according to claim 2, wherein the linking group is a biphenyldiyl group.

8. The light-emitting device according to claim 7, wherein the biphenyldiyl group is a 3,3′-biphenyldiyl group.

9. The light-emitting device according to claim 2, wherein a triplet excitation energy level of each of the first organic compound and the second organic compound is higher than the triplet excitation energy level of the exciplex.

10. The light-emitting device according to claim 2, wherein an emission spectrum of the exciplex overlaps with a lowest-energy absorption band of the fluorescent substance.

11. An electronic device comprising:
the light-emitting device according to claim 2; and
at least one of a sensor, an operation button, a speaker, and a microphone.

12. A lighting device comprising:
the light-emitting device according to claim 2; and
a housing.

13. The light-emitting device according to claim 3, wherein the singlet excitation energy of the exciplex is transferred from the singlet excitation energy level of the exciplex to a singlet excitation energy level of the fluorescent substance.

14. The light-emitting device according to claim 13, wherein fluorescence is emitted from the singlet excitation energy level of the fluorescent substance.

15. The light-emitting device according to claim 3, wherein a 9-position of the carbazole skeleton is bonded to the linking group.

16. The light-emitting device according to claim 3, wherein the linking group is a biphenyldiyl group.

17. The light-emitting device according to claim 16, wherein the biphenyldiyl group is a 3,3′-biphenyldiyl group.

18. The light-emitting device according to claim 3, wherein a triplet excitation energy level of each of the first organic compound and the second organic compound is higher than the triplet excitation energy level of the exciplex.

19. The light-emitting device according to claim 3, wherein an emission spectrum of the exciplex overlaps with a lowest-energy absorption band of the fluorescent substance.

20. An electronic device comprising:
the light-emitting device according to claim 3; and
at least one of a sensor, an operation button, a speaker, and a microphone.

21. A lighting device comprising:
the light-emitting device according to claim 3; and
a housing.
